(19) United States
(12) Patent Application Publication
(10) Pub. No.: US 2025/0338449 A1
(43) Pub. Date: Oct. 30, 2025

(54) ELECTRONIC DEVICE INCLUDING POROUS HEAT DISSIPATION STRUCTURE

(71) Applicant: Samsung Electronics Co., Ltd., Suwon-si (KR)

(72) Inventors: Seokkan KI, Suwon-si (KR); Chorim KIM, Suwon-si (KR); Joseph AHN, Suwon-si (KR); Haejin LEE, Suwon-si (KR); Jonghyun LIM, Suwon-si (KR); Hyeon CHO, Suwon-si (KR)

(21) Appl. No.: 19/177,004

(22) Filed: Apr. 11, 2025

Related U.S. Application Data
(63) Continuation of application No. PCT/KR2025/004373, filed on Apr. 2, 2025.

(30) Foreign Application Priority Data
Apr. 30, 2024 (KR) 10-2024-0058089
Jul. 22, 2024 (KR) 10-2024-0096676
Sep. 19, 2024 (KR) 10-2024-0126733

(51) Int. Cl. H05K 7/20; G06F 1/20

(52) U.S. Cl. CPC H05K 7/20454; H05K 7/20263; H05K 7/20409; H05K 7/20509; H05K 7/20518; G06F 1/203

(57) ABSTRACT

According to an embodiment of the disclosure, an electronic device may comprise: a housing including a plate, a display disposed on a front surface of the plate, a circuit board disposed inside the housing and including an electronic component, and a thermal interface material configured to transfer heat generated from the electronic component to another component included in the electronic device. The thermal interface material may include: a porous foam configured to cover at least a portion of an outer surface of the electronic component, and at least partially disposed between a rear surface of the plate and the circuit board, and a liquid metal included in the porous foam.

### CROSS-REFERENCE TO RELATED APPLICATIONS

This application is a continuation of International Application No. PCT/KR2025/004373 designating the United States, filed on Apr. 2, 2025, in the Korean Intellectual Property Receiving Office and claiming priority to Korean Patent Application Nos. 10-2024-0058089, filed on Apr. 30, 2024, 10-2024-0096676, filed on Jul. 22, 2024, and 10-2024-0126733, filed on Sep. 19, 2024, in the Korean Intellectual Property Office, the disclosures of each of which are incorporated by reference herein in their entireties.

### BACKGROUND

### Field

The disclosure relates to an electronic device, e.g., an electronic device including a porous heat dissipation structure.

### Description of Related Art

Advancing information communication technologies and semiconductor technologies accelerate the spread and use of various electronic devices. Electronic devices are being developed to carry out communication while carried on.

The term “electronic device” may refer, for example, to a device performing a particular function according to its equipped program, such as a home appliance, an electronic scheduler, a portable multimedia player, a mobile communication terminal, a tablet PC, a video/sound device, a desktop PC or laptop computer, a navigation for automobile, etc. For example, the electronic devices may output stored information as voices or images. As electronic devices are highly integrated, and high-speed, high-volume wireless communication becomes commonplace, an electronic device, such as a mobile communication terminal, is being equipped with various functions. For example, an electronic device comes with the integrated functionality, including an entertainment function, such as playing video games, a multimedia function, such as replaying music/videos, a communication and security function, such as for mobile banking, and a scheduling or e-wallet function. These electronic devices have been downsized to be conveniently carried by users.

The above-described information may be provided as related art for the purpose of helping understanding of the disclosure. No claim or determination is made as to whether any of the foregoing is applicable as background art in relation to the disclosure.

### SUMMARY

According to an example embodiment of the disclosure, an electronic device may comprise: a housing including a plate, a display disposed on a front surface of the plate, a circuit board disposed inside the housing and including an electronic component, and a thermal interface material configured to transfer heat generated from the electronic component to another component included in the electronic device. The thermal interface material may include a porous foam configured to cover at least a portion of an outer surface of the electronic component, and at least partially disposed between a rear surface of the plate and the circuit board, and a liquid metal included in the porous foam.

According to an example embodiment of the disclosure, an electronic device may comprise: a housing, an electronic component received in the housing, and a thermal interface material disposed to overlap at least a partial area of one surface of the electronic component. At least a portion of the thermal interface material may form a porous foam including one or more pores substantially filled with a liquid metal.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG. 1 is a block diagram illustrating an example electronic device in a network environment according to an embodiment;

FIG. 2 is a front perspective view illustrating an electronic device according to an embodiment;

FIG. 3 is a rear perspective view illustrating an electronic device according to an embodiment;

FIG. 4 is a front exploded perspective view illustrating an electronic device according to an embodiment;

FIG. 5 is a rear exploded perspective view illustrating an electronic device according to an embodiment;

FIG. 6A is a cross-sectional view of a circuit board and an electronic device, taken along line A-A′ of FIG. 4 according to an embodiment;

FIG. 6B is a cross-sectional view of a circuit board and an electronic device, taken along line A-A′ of FIG. 4 according to an embodiment;

FIG. 6C is a cross-sectional view taken along line D-D′ of FIG. 6A according to an embodiment;

FIG. 7 is a cross-sectional view illustrating a circuit board and an electronic device according to an embodiment;

FIG. 8A is an enlarged view of portion B of FIG. 7 according to an embodiment;

FIG. 8B is an enlarged view of portion C of FIG. 7 according to an embodiment;

FIG. 9 is a cross-sectional view illustrating a board structure according to an embodiment;

FIG. 10 is a cross-sectional view illustrating a circuit board and an electronic device according to an embodiment;

FIG. 11 is a cross-sectional view illustrating a second electronic component, a heat transfer block, and a thermal interface material according to an embodiment;

FIG. 12 is a cross-sectional view illustrating a board structure according to an embodiment; and

FIG. 13 is a cross-sectional view illustrating a board structure according to an embodiment.

### DETAILED DESCRIPTION

Hereinafter, various example embodiments of the disclosure are described in greater detail with reference to the drawings. However, the disclosure may be implemented in other various forms and is not limited to the example embodiments set forth herein. The same or similar reference denotations may be used to refer to the same or similar elements throughout the disclosure and the drawings. Further, for clarity and brevity, no description may be made of well-known functions and configurations in the drawings and relevant descriptions.

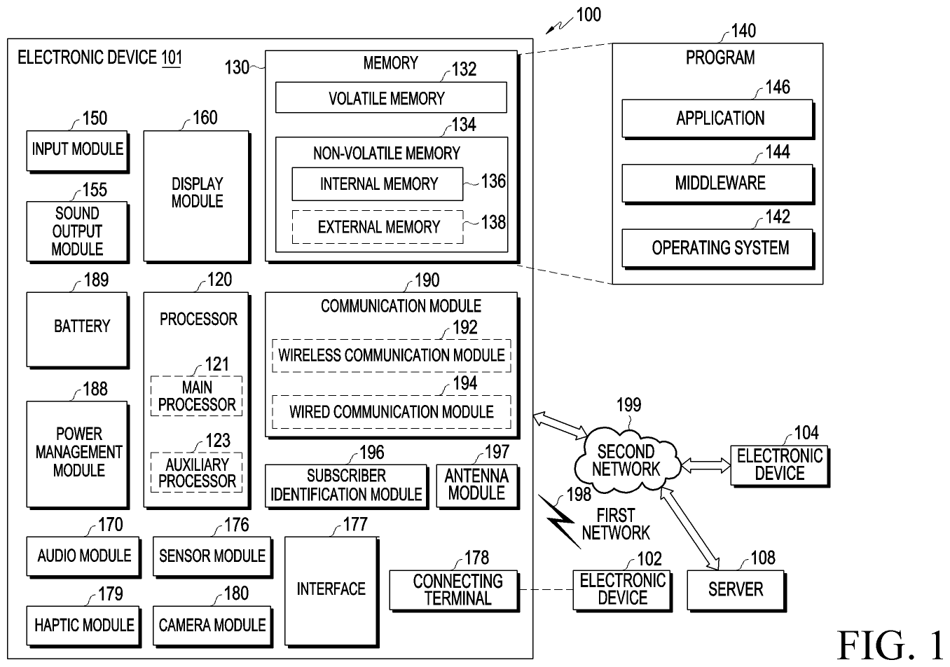

FIG. 1 is a block diagram illustrating an example electronic device 101 in a network environment 100 according to an embodiment.

Referring to FIG. 1, the electronic device 101 in the network environment 100 may communicate with at least one of an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In an embodiment, at least one (e.g., the connecting terminal 178) of the components may be omitted from the electronic device 101, or one or more other components may be added in the electronic device 101. According to an embodiment, some (e.g., the sensor module 176, the camera module 180, or the antenna module 197) of the components may be integrated into a single component (e.g., the display module 160).

The processor 120 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions. The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be configured to use lower power than the main processor 121 or to be specified for a designated function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. The artificial intelligence model may be generated via machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network

(BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by other component (e.g., the processor 120) of the electronic device 101, from the outside (e.g., a user) of the electronic device 101. The input module 150 may include, for example, a microphone, a mouse, a keyboard, keys (e.g., buttons), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display 160 may include, for example, a display, a hologram device, or a projector and control circuitry to control a corresponding one of the display, hologram device, and projector. According to an embodiment, the display 160 may include a touch sensor configured to detect a touch, or a pressure sensor configured to measure the intensity of a force generated by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an accelerometer, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, an HDMI connector, a USB connector, an SD card connector, or an audio connector (e.g., a headphone connector).

The haptic module 179 may convert an electrical signal into a mechanical stimulus (e.g., a vibration or motion) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device 104 via a first network 198 (e.g., a short-range communication network, such as Bluetooth™, wireless-fidelity (Wi-Fi) direct, or infrared data association (IrDA)) or a second network 199 (e.g., a long-range communication network, such as a legacy cellular network, a 5G network, a next-generation communication network, the Internet, or a computer network (e.g., local area network (LAN) or wide area network (WAN)). These various types of communication modules may be implemented as a single component (e.g., a single chip), or may be implemented as multi components (e.g., multi chips) separate from each other. The wireless communication module 192 may identify or authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device). According to an embodiment, the antenna module 197 may include one antenna including a radiator formed of a conductor or conductive pattern formed on a substrate (e.g., a printed circuit board (PCB)). According to an embodiment, the antenna module 197 may include a plurality of antennas (e.g., an antenna array). In this case, at least one antenna appropriate for a communication scheme used in a communication network, such as the first network 198 or the second network 199, may be selected from the plurality of antennas by, e.g., the communication module 190. The signal or the power may then be transmitted or received between the communication module 190 and the external electronic device via the selected at least one antenna. According to an embodiment, other parts (e.g., radio frequency integrated circuit (RFIC)) than the radiator may be further formed as part of the antenna module 197.

According to an embodiment, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. The external electronic devices 102 or 104 each may be a device of the same or a different type from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an Internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or health-care) based on 5G communication technology or IoT-related technology.

The electronic device according to an embodiment of the disclosure may be one of various types of electronic devices. The electronic devices may include, for example, a portable communication device (e.g., a smartphone), a computer device, a portable multimedia device, a portable medical device, a camera, a wearable device, a home appliance, or the like. According to an embodiment of the disclosure, the electronic devices are not limited to those described above.

It should be appreciated that an embodiment of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), the element may be coupled with the other element directly (e.g., wiredly), wirelessly, or via a third element.

As used herein, the term “module” may include a unit implemented in hardware, software, or firmware, or any combination thereof, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

An embodiment as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The storage medium readable by the machine may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program products may be traded as commodities between sellers and buyers. The computer program product may be distributed in the form of a machine-readable storage medium (e.g., compact disc read only memory (CD-ROM)), or be distributed (e.g., downloaded or uploaded) online via an application store (e.g., Play Store™), or between two user devices (e.g., smartphones) directly. If distributed online, at least part of the computer program product may be temporarily generated or at least temporarily stored in the machine-readable storage medium, such as memory of the manufacturer's server, a server of the application store, or a relay server.

According to an embodiment, each component (e.g., a module or a program) of the above-described components may include a single entity or multiple entities. Some of the plurality of entities may be separately disposed in different components. According to an embodiment, one or more of the above-described components may be omitted, or one or more other components may be added. Alternatively or additionally, a plurality of components (e.g., modules or programs) may be integrated into a single component. In such a case, according to an embodiment, the integrated component may still perform one or more functions of each of the plurality of components in the same or similar manner as they are performed by a corresponding one of the plurality of components before the integration. According to an embodiment, operations performed by the module, the program, or another component may be carried out sequentially, in parallel, repeatedly, or heuristically, or one or more of the operations may be executed in a different order or omitted, or one or more other operations may be added.

The drawings below illustrate an orthogonal coordinate system defined and interpreted with X-axis, Y-axis, and Z-axis being orthogonal to each other. Hereinafter, for convenience of description, the X-axis direction may be defined and interpreted as the width direction of the electronic device or components of the electronic device, the Y-axis direction may be defined and interpreted as the length direction of the electronic device or components of the electronic device, and the Z-axis direction may be defined and interpreted as the height direction (or thickness direction) of the electronic device or components of the electronic device. The electronic devices or components of the electronic devices of the disclosure are not limited by the above orientations.

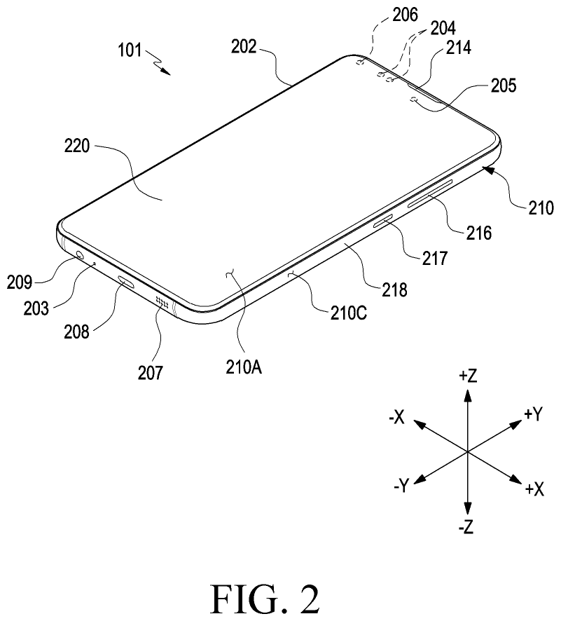

FIG. 2 is a front perspective view illustrating an electronic device according to an embodiment.

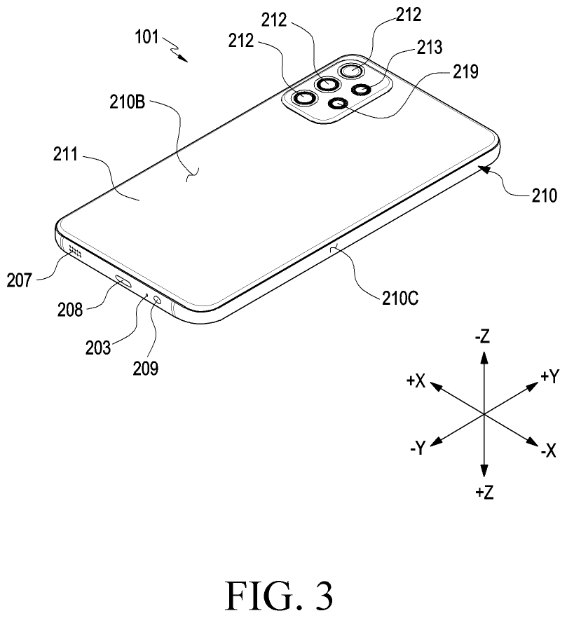

FIG. 3 is a rear perspective view illustrating an electronic device according to an embodiment.

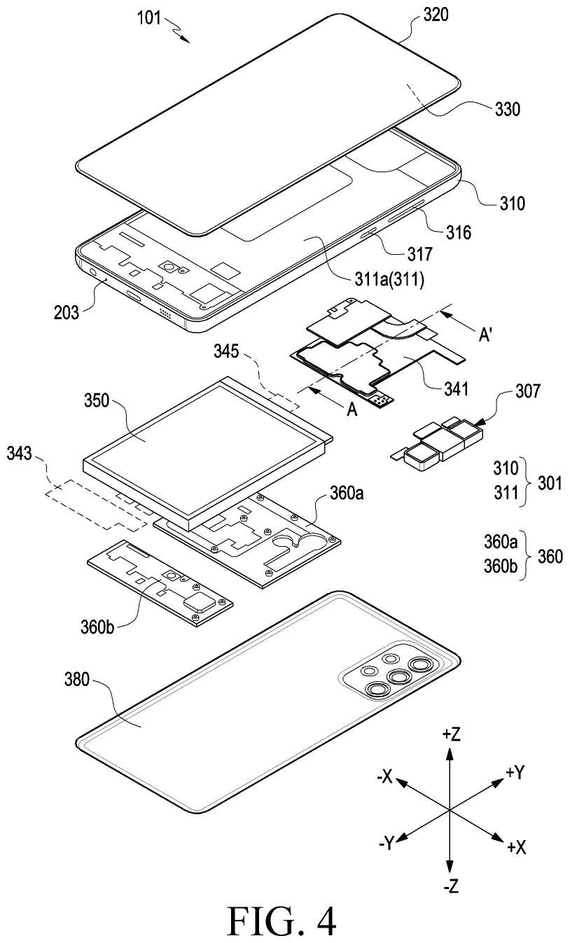

The embodiments of FIGS. 2 and 3 may be combined with an embodiment of FIG. 1 or of FIGS. 4, 5, 6A, 6B, 6C, 7, 8A, 8B, 9, 10, 11, 12 and 13.

Referring to FIGS. 2 and 3, according to an embodiment, an electronic device 101 (e.g., the electronic device 101 of FIG. 1) may include a housing 210 including a first surface (or front surface) 210A, a second surface (or rear surface) 210B, and a side surface 210C surrounding a space between the first surface 210A and the second surface 210B. In an embodiment, the housing 210 may denote a structure forming the first surface 210A of FIG. 2, the second surface 210B of FIG. 3, and some of the side surfaces 210C. According to an embodiment, at least part of the first surface 210A may have a substantially transparent front plate 202 (e.g., a glass plate or polymer plate including various coat layers). The second surface 210B may be formed by a rear plate 211 that is substantially opaque. The rear plate 211 may be formed of, e.g., laminated or colored glass, ceramic, polymer, metal (e.g., aluminum, stainless steel (STS), or magnesium), or a combination of at least two thereof. The side surface 210C may be formed by a side structure (or “side bezel structure”) 218 that couples to the front plate 202 and the rear plate 211 and includes a metal and/or polymer. In an embodiment, the rear plate 211 and the side structure 218 may be integrally formed together and include the same material (e.g., a metal, such as aluminum).

Although not shown, the front plate 202 may include area(s) that bend from at least a portion of an edge toward the rear plate 211 and seamlessly extend. In an embodiment, only one of the areas of the front plate 202 (or the rear plate 211), which bend to the rear plate 211 (or front plate 202) and extend may be included in one edge of the first surface 210A. According to an embodiment, the front plate 202 or the rear plate 211 may have a substantially flat plate shape. For example, the front plate 202 or the rear plate 211 may not include a bending and extending area. When an area bending and extending is included in the front plate 202 or rear plate 211, the thickness of the electronic device 101 at the portion including the area bending and extending may be smaller than the thickness of the rest.

According to an embodiment, the electronic device 101 may include at least one or more of a display 220, audio modules 203, 207, and 214, sensor modules 204 and 219, camera modules 205, 212, and 213, key input devices 216 and 217, a light emitting device 206, and connector holes 208 and 209. In an embodiment, the electronic device 101 may exclude at least one (e.g., the key input devices 216 and 217 or the light emitting device 206) of the components or may add other components.

The display 220 may be visible through a significant portion of the front plate 202. In an embodiment, at least a portion of the display 220 may be visible through the front plate 202 forming the first surface 210A, or through a portion of the side surface 210C. In an embodiment, the edge of the display 220 may be formed to be substantially the same in shape as an adjacent outer edge of the front plate 202. In an embodiment (not illustrated), the interval between the outer edge of the display 220 and the outer edge of the front plate 202 may remain substantially even to give a larger area of visual exposure of the display 220.

In an embodiment, the screen display area of the display 220 may have a recess or opening in a portion thereof, and the electronic device 101 may include at least one or more of the audio module 214, sensor module 204, camera module 205, and light emitting device 206 aligned with the recess or opening. In an embodiment, at least one or more of the audio module 214, sensor module 204, camera module 205, fingerprint sensor, and light emitting device 206 may be included on the rear surface of the screen display area of the display 220. In an embodiment, the display 220 may be disposed to be coupled with, or adjacent, a touch detecting circuit, a pressure sensor capable of measuring the strength (pressure) of touches, and/or a digitizer for detecting a magnetic field-type stylus pen.

According to an embodiment, the camera module 205 may be configured to capture forward of the display 220 through a camera opening formed in the display 220. The camera module 205 may be covered by the front plate 202. The camera module 205 may include an under display camera (UDC) that may not be visually exposed through the display 220 but hidden. The display rear camera may be configured to capture an external object through the camera opening of the display 220.

The audio modules 203, 207, and 214 may include a microphone hole 203 and speaker holes 207 and 214. A microphone for obtaining external sounds through the microphone hole 203 may be disposed in the housing 210. In an embodiment, a plurality of microphones may be disposed to detect the direction of the sound. The speaker holes 207 and 214 may include an external speaker hole 207 and a phone receiver hole 214. In an embodiment, the speaker holes 207 and 214 and the microphone hole 203 may be implemented as a single hole, or speakers may be rested without the speaker holes 207 and 214 (e.g., piezo speakers).

According to an embodiment, the call receiver hole 214 may form a path for transferring the sound generated from the speaker disposed inside the housing 210 to the outside of the electronic device 101.

According to an embodiment, the call receiver hole 214 may be defined by the housing 210. According to an embodiment, the call receiver hole 214 may be formed between a portion (e.g., at least a portion of an edge facing in the +Y direction of FIGS. 2 and 3) of the housing 210 and an upper edge of the display 220, but is not limited thereto.

The sensor modules 204 and 219 may generate an electrical signal or data value corresponding to an internal operating state or external environmental state of the electronic device 101. For example, the sensor modules 204 and 219 may include a first sensor module 204 (e.g., a proximity sensor) and/or a second sensor module (e.g., a fingerprint sensor), which is disposed on the first surface 210A of the housing 210, and/or a third sensor module 219 and/or a fourth sensor module (e.g., a fingerprint sensor) disposed on the second surface 210B of the housing 210. The fingerprint sensor may be disposed on the second surface 210B or side surface 210C as well as the first surface 210A (e.g., the display 220) of the housing 210. The electronic device 101 may further include, e.g., at least one of a gesture sensor, a gyro sensor, an atmospheric pressure sensor, a magnetic sensor, an acceleration sensor, a grip sensor, a color sensor, an infrared (IR) sensor, a biometric sensor, a temperature sensor, a humidity sensor, or an illuminance sensor.

The camera modules 205, 212, and 213 may include a first camera device 205 disposed on the first surface 210A of the electronic device 101, and a second camera device 212 and/or a flash 213 disposed on the second surface 210B. The camera devices 205 and 212 may include one or more lenses, an image sensor, and/or an image signal processor. The flash 213 may include, e.g., a light emitting diode (LED) or a xenon lamp. In an embodiment, two or more lenses (an infrared (IR) camera, a wide-angle lens, and a telescopic lens) and image sensors may be disposed on one surface of the electronic device 101. In an embodiment, flash 213 may emit infrared light. The infrared light emitted by the flash 213 and reflected by the subject may be received through the third sensor module 219. The electronic device 101 or the processor of the electronic device 101 may detect depth information about the subject based on the time point when the infrared light is received from the third sensor module 219.

The key input devices 216 and 217 may be disposed on one surface of the housing 210. For example, the key input devices 216 and 217 may be disposed on the side surface 210C of the housing 210. In an embodiment, the electronic device 101 may exclude all or some of the above-mentioned key input devices 216 and 217 and the excluded key input devices may be implemented in other forms, e.g., as soft keys, on the display 220. In an embodiment, the key input devices 216 and 217 may include the sensor module disposed on the second surface 210B of the housing 210.

According to an embodiment, the key input device 216 and 217 may be defined and/or referred to as a side key, a key input module, or a button assembly.

According to an embodiment, the key input device 216 and 217 may include a volume key 216 or a power key 217. The volume key 216 may be a key capable of adjusting the intensity of the sound signal output from the electronic device 101. The volume key 216 may have an elongated shape when viewed from a side surface of the electronic device 101 (e.g., when viewed from the +X direction to the-X direction of FIGS. 2 and 3). As the volume key 216 is provided in the elongated shape, a key input for volume up may be possible on one side of the volume key 216, and a key input for volume down may be possible on the other side of the volume key 216. For example, when viewed from the side surface of the electronic device 101, the volume key 216 may be viewed as a single member, but the volume key 216 may provide two key input points. The volume key 216 is configured to be able to adjust the intensity of sound signal but, without limitations thereto, may provide scroll up-down adjustment, text size adjustment, or other key input functions.

According to an embodiment, the power key 217 may be spaced apart from the volume key 216. The power key 217 may be configured to be able to adjust the on-off of the electronic device 101 or to adjust the standby mode or activation mode of the electronic device 101.

The light emitting device 206 may be disposed on, e.g., the first surface 210A of the housing 210. The light emitting device 206 may provide, e.g., information about the state of the electronic device 101 in the form of light. In an embodiment, the light emitting device 206 may provide a light source that interacts with, e.g., the camera module 205. The light emitting device 206 may include, e.g., a light emitting diode (LED), an infrared (IR) LED, or a xenon lamp.

The connector holes 208 and 209 may include a first connector hole 208 for receiving a connector (e.g., a universal serial bus (USB) connector) for transmitting or receiving power and/or data to/from an external electronic device and/or a second connector hole 209 (e.g., an earphone jack) for receiving a connector for transmitting or receiving audio signals to/from the external electronic device.

FIG. 4 is a front exploded perspective view illustrating an electronic device according to an embodiment.

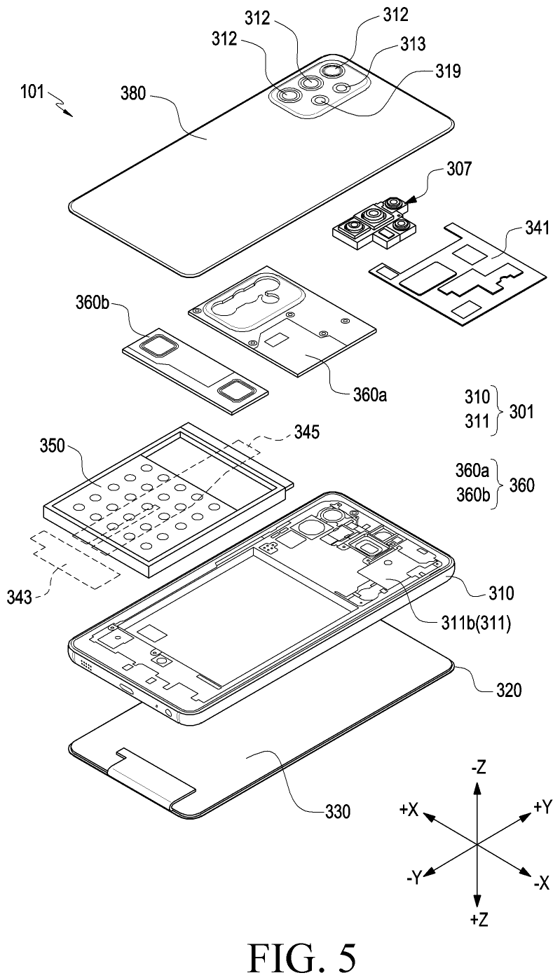

FIG. 5 is a rear exploded perspective view illustrating an electronic device according to an embodiment.

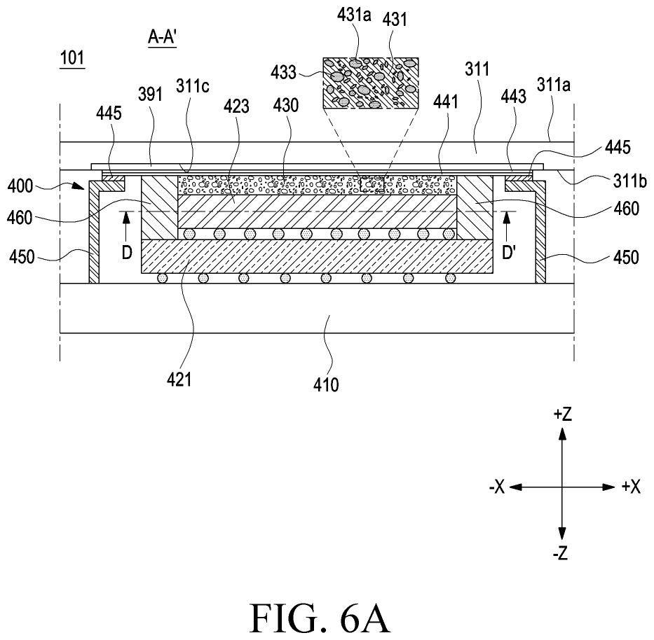

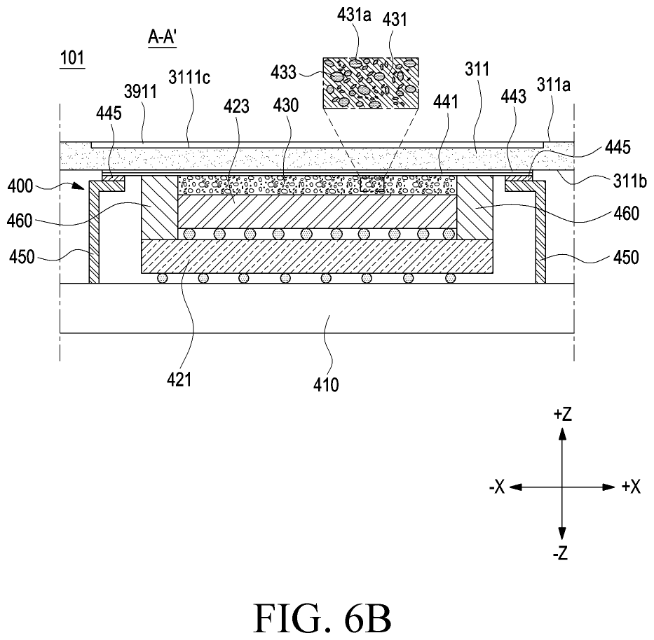

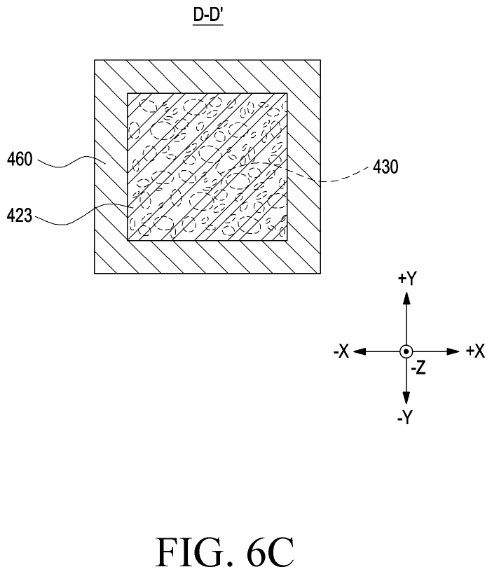

The embodiments of FIGS. 4 and 5 may be combined with the embodiments of FIGS. 1, 2 and 3, and/or the embodiments of FIGS. 6A, 6B 6C, 7, 8A, 8B, 9, 10, 11, 12 and 13.

Referring to FIGS. 4 and 5, an electronic device 101 (e.g., the electronic device 101 of FIG. 1 or the electronic device 101 of FIGS. 2 and 3) may include a side structure 310, a first plate 311, a front plate 320 (e.g., the front plate 202 of FIG. 2), a display 330 (e.g., the display 220 of FIG. 2), at least one printed circuit board (or a board assembly) 341 or 343, a battery 350, a second plate 360 (e.g., a rear case), an antenna, a camera assembly 307, and a rear plate 380 (e.g., the rear plate 211 of FIG. 2). When including a plurality of printed circuit boards 341 and 343, the electronic device 101 may electrically connect the different printed circuit boards by including at least one flexible connection member 345. For example, the printed circuit boards 341 and 343 may include a first circuit board 341 disposed above the battery 350 (e.g., in the +Y-axis direction) and a second circuit board 343 disposed under the battery 350 (e.g., in the −Y-axis direction), and the flexible connection member 345 may electrically connect the first circuit board 341 and the second circuit board 343.

According to an embodiment, the electronic device 101 may omit at least one (e.g., the second plate 360) of the components or may add other components. At least one of the components of the electronic device 101 may be the same or similar to at least one of the components of the electronic device 101 of FIGS. 1 to 3 and no duplicate description is made below.

According to an embodiment, the electronic device 101 may include a housing 301 (e.g., the housing 210 of FIGS. 2 and 3).

According to an embodiment, the housing 310 may include a first plate 311 and a side structure 311 (e.g., the side structure 218 or the side surface 210C of FIGS. 2 and 3).

According to an embodiment, at least a portion of the first plate 311 may be provided in a flat plate shape. In an embodiment, the first plate 311 may be disposed inside the electronic device 101 to be connected to the side structure 310, or may be integrally formed with the side structure 310. The first plate 311 may be formed of, e.g., a metal material and/or a non-metal material (e.g., polymer). When the first plate 311 is at least partially formed of a metal material, the side structure 310 or a portion of the first plate 311 may function as an antenna. The first plate 311 may be defined and/or referred to as a first supporting member 311, a first supporting plate 311, or a first bracket.

According to an embodiment, the first plate 311 may include a front surface 311a and a rear surface 311b opposite to the front surface 311b. The front surface 311a may be defined and/or referred to as a first surface 311a or a front side 311a. The rear surface 311b may be defined and/or referred to as a second surface 311b or a rear side 311b.

According to an embodiment, the front surface 311a may face the display 330. For example, the display 330 may be supported by the front surface 311a. The rear surface 311b may face the rear plate 380.

According to an embodiment, the display 330 may be coupled to the front surface 311a of the first plate 311, and the printed circuit boards 341 and 343 may be coupled to the rear surface 311b of the first plate 311. A processor, memory, and/or interface may be mounted on the printed circuit boards 341 and 343. The processor may include one or more of, e.g., a central processing unit, an application processor, a graphic processing device, an image signal processing, a sensor hub processor, or a communication processor.

According to an embodiment, the first plate 311 and the side structure 310 may be collectively referred to as a front case or a housing 301. According to an embodiment, the housing 301 may be generally understood as a structure for receiving, protecting, or disposing the printed circuit boards 341 and 343 or the battery 350. In an embodiment, the housing 301 may be understood as including a structure that the user may visually or tactfully recognize from the exterior of the electronic device 101, e.g., the side structure 310, the front plate 320, and/or the rear plate 380. In an embodiment, the ‘front or rear surface of the housing 301’ may refer to the first surface 210A of FIG. 2 or the second surface 210B of FIG. 3. In an embodiment, the first plate 311 may be disposed between the front plate 320 (e.g., the first surface 210A of FIG. 2) and the rear plate 380 (e.g., the second surface 210B of FIG. 3) and may function as a structure for placing an electrical/electronic component, such as the printed circuit boards 341 and 343 or the camera assembly 307.

According to an embodiment, the memory may include a volatile memory (e.g., the volatile memory 132 of FIG. 1) or a non-volatile memory (e.g., the non-volatile memory 134 of FIG. 1).

According to an embodiment, the interface may include, e.g., a high definition multimedia interface (HDMI), a universal serial bus (USB) interface, a secure digital (SD) card interface, and/or an audio interface. The interface may electrically or physically connect, e.g., the electronic device 101 with an external electronic device and may include a USB connector, an SD card/multimedia card (MMC) connector, or an audio connector.

According to an embodiment, the second plate 360 may include, e.g., an upper supporting member 360a and a lower supporting member 360b. In an embodiment, the upper supporting member 360a, together with a portion of the first plate 311, may be disposed to surround the printed circuit boards 341 and 343 (e.g., the first circuit board 341). For example, the upper supporting member 360a of the second plate 360 may be disposed to face the first plate 311 with the first circuit board 341 interposed therebetween. In an embodiment, the lower supporting member 360b of the second plate 360 may be disposed to face the first plate 311 with the second circuit board 343 interposed therebetween. A circuit device (e.g., a processor, a communication module, or memory) implemented in the form of an integrated circuit chip or various electrical/electronic components may be disposed on the circuit boards 341 and 343. According to an embodiment, the circuit boards 341 and 343 may receive an electromagnetic shielding environment from the second plate 360. In an embodiment, the lower supporting member 360b may be utilized as a structure in which electrical/electronic components, such as a speaker module and an interface (e.g., a USB connector, an SD card/MMC connector, or an audio connector) may be disposed. In an embodiment, electrical/electronic components, such as a speaker module and an interface (e.g., a USB connector, an SD card/MMC connector, or an audio connector) may be disposed on an additional printed circuit board (not shown). For example, the lower supporting member 360b, together with the other part of the first plate 311, may be disposed to surround the additional circuit board. The speaker module or interface disposed on the additional circuit board (not shown) or the lower supporting member 360b may be disposed corresponding to the audio module 207 or connector holes 208 and 209 of FIG. 2. The second plate 360 may be defined and/or referred to as a second supporting member 360, a second supporting plate 360, or a second bracket.

According to an embodiment, the battery 350 may be a device for supplying power to at least one component of the electronic device 101. The battery 189 may include, e.g., a primary cell which is not rechargeable, a secondary cell which is rechargeable, or a fuel cell. At least a portion of the battery 350 may be disposed on substantially the same plane as the printed circuit boards 341 and 343. The battery 350 may be integrally or detachably disposed inside the electronic device 101.

Although not shown, the antenna may include a conductor pattern implemented on the surface of the second plate 360 through, e.g., laser direct structuring. In an embodiment, the antenna may include a printed circuit pattern formed on the surface of the thin film. The thin film-type antenna may be disposed between the rear plate 380 and the battery 350. The antenna may include, e.g., a near-field communication (NFC) antenna, a wireless charging antenna, and/or a magnetic secure transmission (MST) antenna. The antenna may perform short-range communication with, e.g., an external device or may wirelessly transmit or receive power necessary for charging. In an embodiment of the disclosure, another antenna structure may be formed by a portion or combination of the side structure 310 and/or the first plate 311.

According to an embodiment, the camera assembly 307 may include at least one camera module. Inside the electronic device 101, the camera assembly 307 (or at least one camera module) may receive at least a portion of the light incident through the optical hole or the camera windows 312, 313, and 319. In an embodiment, the camera assembly 307 may be disposed on the first plate 311 in a position adjacent to the printed circuit boards 341 and 343. In an embodiment, the camera module(s) of the camera assembly 307 may be generally aligned with either one of the camera windows 312, 313, and 319 and be a least partially surrounded by the second plate 360 (e.g., the upper supporting member 360a).

According to an embodiment, the electronic device 101 may include a flexible connection member 345. The flexible connection member 345 may include a flexible flat cable (FFC), a flexible printed circuit board (FPCB), or a board to board (B2B) connector.

According to an embodiment, the flexible connection member 345 is at least partially bendable. For example, the flexible connection member 345 may be configured to be at least partially folded or unfolded.

According to an embodiment, the flexible connection member 345 may electrically connect the first circuit board 341 (e.g., a main circuit board) and at least one electrical component. For example, one end of the flexible connection member 345 may be physically and/or electrically connected to at least a portion of the first circuit board 341. For example, the other end of the flexible connection member 345 may be physically and/or electrically connected to at least a portion of the at least one electrical component. The at least one electrical component may include, e.g., a second circuit board 343 (e.g., a sub circuit board). However, at least one electrical component is not limited thereto but may include various electrical components (e.g., antenna, speaker, battery, display or sensor).

According to an embodiment, the flexible connection member 345 may be configured to transfer power or electrical signals from the first circuit board 341 to at least one electrical component. The flexible connection member 345 may be configured to transfer power or electrical signals from at least one electrical component to the first circuit board 341. The electrical signals may include control signals, power signals, or communication signals.

According to an embodiment, the electronic device 101 may include key input devices 316 and 317 (e.g., the key input devices 216 and 217 of FIG. 2). The key input devices 316 and 317 may include a volume key 316 (e.g., the volume key 216 of FIG. 2) or a power key (e.g., the power key 217 of FIG. 2).

According to an embodiment, the volume key 316 may be disposed on one surface of the housing 301. For example, the volume key 316 may be disposed on a portion of the lateral surface (also referred to as a side surface) of the housing 301 (e.g., the side structure 310 of FIG. 4), but is not limited thereto.

According to an embodiment, the volume key 316 may include a haptic module (e.g., the haptic module 179 of FIG. 1). The haptic module may include a piezo actuator. The piezo actuator may be configured to provide the user with a mechanical stimulus (e.g., vibration or movement) that may be perceived through tactile or motor sensation when the user presses or touches the volume key 316.

According to an embodiment, the volume key 316 may have an elongated shape when viewed from a side surface of the electronic device 101 (e.g., when viewed from the +X direction to the −X direction of FIG. 4). The volume key 316 may be spaced apart from the power key 317.

FIG. 6A is a cross-sectional view of a circuit board and an electronic device, taken along line A-A′ of FIG. 4 according to an embodiment.

FIG. 6B is a cross-sectional view of a circuit board and an electronic device, taken along line A-A′ of FIG. 4 according to an embodiment.

FIG. 6C is a cross-sectional view taken along line D-D′ of FIG. 6A according to an embodiment.

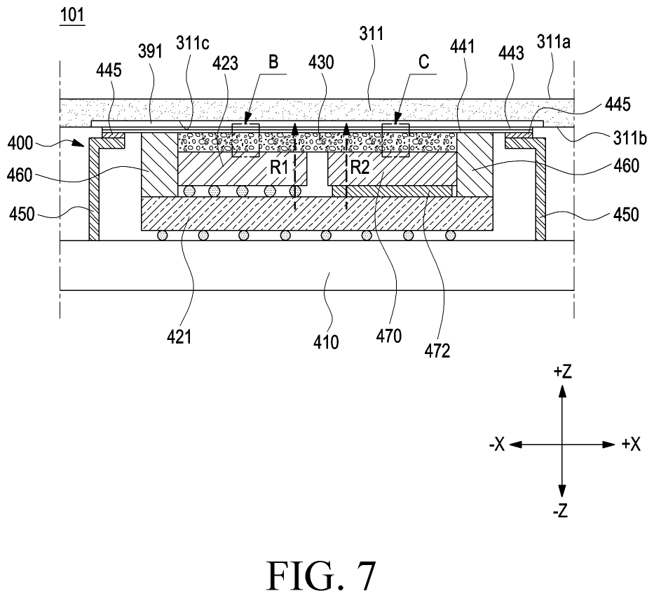

FIG. 7 is a cross-sectional view illustrating a circuit board and an electronic device according to an embodiment.

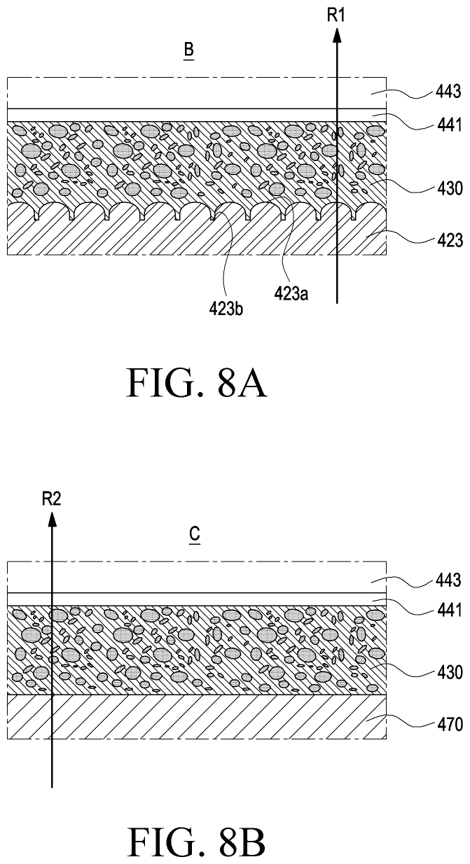

FIG. 8A is an enlarged view of portion B of FIG. 7 according to an embodiment.

FIG. 8B is an enlarged view of portion C of FIG. 7 according to an embodiment.

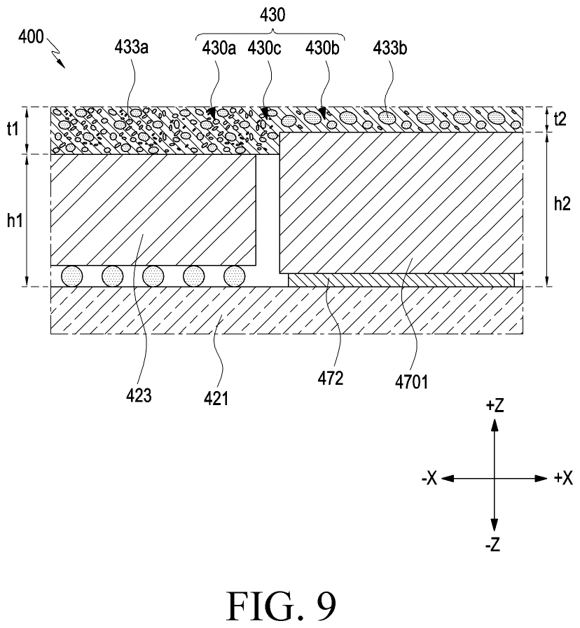

The embodiments of FIGS. 6A, 6B, 6C, 7, 8A and 8B may be combined with the embodiments of FIGS. 1, 2, 3, 4 and 5 (which may be referred to as FIGS. 1 to 5) and/or the embodiments of FIGS. 9, 10, 11, 12 and 13 (which may be referred to as FIGS. 9 to 13).

The configurations of the embodiments of FIGS. 6A, 6B, 6C, 7, 8A and 8B may be identical in whole or part to the configuration of the configurations of the embodiments of FIGS. 1 to 5 or the configurations of the embodiments of FIGS. 9 to 13.

Referring to FIGS. 6A, 6B, 6C and 7, an electronic device 101 (e.g., the electronic device 101 of FIGS. 2 to 5) may include a first plate 311 (e.g., the first plate 311 of FIGS. 4 and 5) and a board structure 400 (e.g., the first circuit board 341 of FIGS. 4 and 5).

According to an embodiment, the first plate 311 may include a front surface 311a and a rear surface 311b opposite to the front surface 311a.

According to an embodiment, the front surface 311a may be configured to support the display (e.g., the display 330 of FIGS. 4 and 5). For example, the display may be disposed on the front surface 311a.

According to an embodiment, the rear surface 311b may face the board structure 400. For example, the rear surface 311b may contact at least a portion of the board structure 400.

According to an embodiment, the board structure 400 may be disposed inside the housing (e.g., the housing 301 of FIGS. 4 and 5).

According to an embodiment, the board structure 400 may be defined and/or referred to as a board assembly 400.

According to an embodiment, the board structure 400 may include a circuit board 410, at least one electronic component 421 and 423, a thermal interface material (TIM) 430, a shielding member 441, a heat transfer member 443, an adhesive member 445, a shield can 450, and a stopper 460.

According to an embodiment, the circuit board 410 may be disposed inside the housing (e.g., the housing 301 of FIGS. 4 and 5). According to an embodiment, the circuit board 410 may include a printed circuit board (PCB), a flexible printed circuit board (FPCB), or a rigid flexible printed circuit board (RF-PCB).

According to an embodiment, the front surface of the circuit board 410 may face the rear surface 311b of the first plate 311.

According to an embodiment, the board structure 400 may include at least one electronic component 421 and 423.

According to an embodiment, at least one electronic component 421 and 423 may be disposed on one surface of the circuit board 410 of the board structure 400 (e.g., the surface facing in the +Z direction of FIGS. 6A and 6B). According to an embodiment, at least one electronic component 421 and 423 may be disposed on one surface of the circuit board 410 of the board structure 400 (e.g., the surface facing in the +Z direction of FIGS. 6A and 6B).

According to an embodiment, at least one electronic component 421 and 423 may include a first electronic component 421 and a second electronic component 423.

According to an embodiment, the first electronic component 421 may be disposed on the front surface of the circuit board 410 (e.g., the surface facing in the +Z direction in FIGS. 6A and 6B). The first electronic component 421 may be electrically and/or physically connected to the front surface of the circuit board 410 through solder balls.

According to an embodiment, the first electronic component 421 may include a processor (e.g., the processor 120 of FIG. 1), but is not limited thereto. The processor may include an application processor (AP), but is not limited thereto. The first electronic component 421 may include various electronic components that generate heat during operation.

According to an embodiment, the second electronic component 423 may be disposed on the front surface of the first electronic component 421 (e.g., the surface facing in the +Z direction in FIGS. 6A and 6B). The second electronic component 423 may be electrically and/or physically connected to the front surface of the first electronic component 421 through a solder ball.

According to an embodiment, the second electronic component 423 may include memory (e.g., the memory 130 of FIG. 1), but is not limited thereto. For example, the memory may include dynamic random access memory (DRAM), but is not limited thereto. The second electronic component 423 may include various electronic components that generate heat during operation.

According to an embodiment, the first electronic component 421 may be disposed on the front surface of the circuit board 410 and may have a first area. For example, the size of the first electronic component 421 may have a first area when viewed from the display (e.g., the display 330 of FIG. 4) toward the circuit board 410 (e.g., when viewed from the +Z direction of FIG. 6A to the −Z direction).

According to an embodiment, the second electronic component 423 may be disposed on the front surface of the first electronic component 421 and may have a second area. For example, the size of the second electronic component 423 may have a second area when viewed from the display toward the circuit board 410 (e.g., when viewed from the +Z direction of FIG. 6A to the −Z direction). The second area may be smaller than the first area.

According to an embodiment, during operation at the same time, the amount of heat generated by the first electronic component 421 may be larger than the amount of heat generated by the second electronic component 423, but is not limited thereto.

According to an embodiment, the thermal interface material (TIM) 430 may be configured to dissipate heat generated from at least one electronic component 421 and 423. For example, thermal interface material 430 may be configured to transfer heat generated from at least one electronic components 421 and 423 to the first plate 311. According to an embodiment, the thermal interface material 430 may be defined and/or referred to as a thermal interface member 430.

According to an embodiment, the thermal interface material 430 may be configured to transfer heat generated from at least one electronic component 421 and 423 to another component (e.g., the shielding member 441, the heat transfer member 443, or the heat diffusion member 391 of FIG. 6A) included in the electronic device.

According to an embodiment, the thermal interface material 430 may be disposed between the first plate 311 and the second electronic component 423. For example, the thermal interface material 430 may contact or be disposed on the rear surface of the first plate 311 (e.g., the surface facing in the −Z direction of FIG. 6A) and the front surface of the second electronic component 423 (e.g., the surface facing in the +Z direction of FIG. 6A). That the thermal interface material 430 contacts or is disposed on the rear surface of the first plate 311 of thermal interface material 430 may be defined and/or interpreted as the thermal interface material 430 contacting or being disposed on the rear surface of the first plate 311 through an intermediate member (e.g., the shielding member 441, the heat transfer member 443, or the heat diffusion member 391 of FIG. 6A).

According to an embodiment, the thermal interface material 430 may include a porous foam 431 and a liquid metal 433 injected into the porous foam 431. The liquid metal 433 may be defined and/or referred to as a filler material filled in the porous foam 431.

According to an embodiment, the porous foam 431 may include a plurality of pores 431a for receiving the liquid metal 433. One or more of the plurality of pores 431a may be substantially filled with liquid metal particles. The plurality of pores 431a may be defined and/or referred to as a plurality of cavities.

According to an embodiment, the porosity of the porous foam 431 may be defined as a ratio of the volume of the plurality of pores 431a to the total volume of the porous foam 431. The porosity of the porous foam 431 may be about 75% to about 99%, but is not limited thereto. The porosity of the porous foam 431 may be about 90%, but is not limited thereto.

According to an embodiment, the pore density of the porous foam 431 may be defined as the number of the plurality of pores 431a per unit length of the porous foam 431. For example, the pore density of the porous foam 431 may be about 20 ppi (pores per inch) to about 150 ppi, which may be defined as having about 20 to 150 pores 431a in one inch. For example, the pore density of the porous foam 431 may be from about 30 ppi to about 140 ppi, but is not limited thereto.

According to an embodiment, the compression ratio of the porous foam 431 may be design-changed by adjusting the porosity and pore density.

According to an embodiment, the porous foam 431 may have compressibility. At about 1 kgf, the compression rate of the porous foam 431 may be from about 23% to about 42%, but is not limited thereto. For example, the compression ratio of the porous foam 431 may be about 25% to about 40%, but is not limited thereto.

According to an embodiment, as the porous foam 431 has compressibility, the thickness of the porous foam 431 (e.g., the thickness in the Z-axis direction of FIG. 6A) may be reduced in the limited inner space of the electronic device 101. For example, when the porous foam 431 tightly contacts the rear surface 311b of the first plate 311 or the heat diffusion member 391, the porous foam 431 may be compressed and its thickness may be reduced in the assembly process of the electronic device 101.

According to an embodiment, when the stopper 460 includes a rigid material and has a relatively low compression strain, the porous foam 431 may be designed to protrude upward (e.g., in the +Z direction) from the upper surface of the stopper 460 (e.g., the surface facing in the +Z direction of FIGS. 6A and 6B). When the porous foam 431 tightly contacts the rear surface 311b of the first plate 311 or the heat diffusion member 391, the porous foam 431 may be compressed and thus the thickness thereof may be reduced. As the porous foam 431 is compressed, the upper surface (e.g., the surface facing in the +Z direction of FIGS. 6A and 6B) of the porous foam 431 may be positioned on the same plane as the upper surface of the stopper 460.

According to an embodiment, when the stopper 460 includes a flexible material and has a relatively high compression strain, the porous foam 431 may be designed to be positioned on the same plane as the upper surface of the stopper 460 (e.g., the surface facing in the +Z direction of FIGS. 6A and 6B). When the porous foam 431 tightly contacts the rear surface 311b of the first plate 311 or the heat diffusion member 391, the porous foam 431 may be compressed and thus the thickness thereof may be reduced. When the porous foam 431 is compressed, the stopper 460 may also be compressed. Accordingly, the upper surface (e.g., the surface facing in the +Z direction of FIGS. 6A and 6B) of the porous foam 431 may be positioned on the same plane as the upper surface of the stopper 460.

According to an embodiment, as the porous foam 431 has compressibility, the flatness of the display (e.g., the display 330 of FIGS. 4 and 5) visually exposed to the user may be enhanced. For example, when the porous foam 431 tightly contacts the rear surface 311b of the first plate 311 or the heat diffusion member 391, the porous foam 431 may be compressed to reduce, limit, and/or prevent excessive pressure from being applied to the first plate 311. Accordingly, the flatness of the display may be enhanced by reducing, limiting, and/or preventing the display supported by the front surface 311a of the first plate 311 from creasing. That the porous foam 431 tightly contacts the rear surface 311b of the first plate 311 or the heat dissipation member 391 may be defined as the porous foam 431 being directly in tight contact with the rear surface 311b of the first plate 311 or heat dissipation member 391, but is not limited thereto. For example, when an intermediate member (e.g., the shielding member 441 and/or heat transfer member 443) is disposed between the porous foam 431 and the rear surface 311b of the first plate 311 or the heat transfer member 391, the tight contact of the porous foam 431 with the rear surface 311b of the first plate 311 or the heat transfer member 391 may be interpreted as including the case where the porous foam 431 is indirectly in tight contact with the rear surface 311b of the first plate 311 or the heat transfer member 391 through the intermediate member.

According to an embodiment, the porous foam 431 may include a copper (Cu) foam, but is not limited thereto.

According to an embodiment, the porous foam 431 may include a single metal foam or a composite metal foam including at least one of copper (Cu), silver (Ag), gold (Au), nickel (Ni), and boron nitride (BN). For example, the porous foam 431 may include at least one of copper (Cu), silver (Ag), gold (Au), nickel (Ni), and hexagonal boron nitride (h-BN).

According to an embodiment, the porous foam 431 may include a polymer material. For example, the porous foam 431 may include, but is not limited to, polydimethylsiloxane (PDMS) or silicone oil.

According to an embodiment, the porous foam 431 may cover at least a portion of the outer surface of at least one electronic component 421 and 423. For example, the porous foam 431 may be applied to the front or upper surface of the second electronic component (423 (e.g., the surface facing in the +Z direction of FIG. 6).

According to an embodiment, the porous foam 431 may be at least partially disposed between the rear surface 311b of the first plate 311 and the second electronic component 423.

According to an embodiment, the porous foam 431 may be defined and/or referred to as a porous matrix or a porous accommodating portion.

According to an embodiment, the liquid metal 433 may be injected into the plurality of pores 431a of the porous foam 431. For example, the liquid metal 433 may include a plurality of liquid metal particles injected into the plurality of pores 431a.

According to an embodiment, the liquid metal 433 may be a metal in a liquid state at room temperature, but is not limited thereto. For example, the liquid metal 433 may be configured to remain in a liquid state when at least one electronic component 421 and 423 generates heat above a designated temperature value.

According to an embodiment, the thermal conductivity of the liquid metal 433 may be larger than that of the porous foam 431. The thermal conductivity of thermal interface material 430 including the liquid metal 433 and the porous foam 431 may be about 17 W/(m×K) to about 33 W/(m×K), but is not limited thereto. According to an embodiment, the thermal conductivity of the thermal interface material 430 may be about 20 W/(m×K) to about 30 W/(m×K), but is not limited thereto.

According to an embodiment, the liquid metal 433 may include a single liquid metal or a composite liquid metal including at least one of gallium (Ga), indium (In), and tin (Sn). For example, the liquid metal 433 may include a eutectic alloy (EGaInSn alloy) of gallium, indium, and tin. When the liquid metal 433 includes a eutectic alloy of gallium, indium, and tin, the composition ratio of the liquid metal may be gallium (about 60 wt % to about 72 wt %), indium (about 20 wt % to about 24 wt %), and tin (about 14 wt % to about 18 wt %), but is not limited thereto.

According to an embodiment, the liquid metal 433 may include a bismuth-based eutectic alloy.

According to an embodiment, the thermal interface material 430 may be disposed between at least one electronic component 421 and 423 and the rear surface 311b of the first plate 311.

According to an embodiment, the thermal interface material 430 may form at least a portion of a heat dissipation path configured to transfer heat generated from at least one electronic component 421 and 423 to the first plate 311.

According to an embodiment, the thermal interface material 430 may be configured to overlap the first electronic component 421 when viewed in a direction (e.g., the Z-axis direction of FIG. 4A) substantially perpendicular to the display. For example, the thermal interface material 430 may overlap the first electronic component 421 when viewed in a direction from the display toward the circuit board 410.

According to an embodiment, the shield can 450 may extend from the front surface of the circuit board 410 toward the first plate 311. The shield can 450 may be disposed to surround at least one electronic component 421 and 423. The shield can 450 may block, limit and/or reduce noise from acting between at least one electronic component 421 and 423 disposed inside the shield can 450 and other electronic components of the electronic device 101 disposed outside the shield can 450.

According to an embodiment, the shielding member 441 may be attached to the front surface of the shield can 450 (e.g., the surface facing in the +Z direction of FIG. 6). The shielding member 441 may include a shielding material. The shielding material may include, but is not limited to, copper. For example, the shielding member 441 may include, but is not limited to, a shielding film, a metal cover, or a metal sheet. The shielding member 441 may be defined and/or referred to as a shielding cover.

According to an embodiment, at least one electronic component 421 and 423 and the thermal interface material 430 may be disposed in the inner space defined or surrounded by the shielding member 441, the shield can 450 and the circuit board 410.

According to an embodiment, the shielding member 441 may block and/or reduce the transmission of electromagnetic noise generated from at least one electronic component 421 and 423 to the display (e.g., the display 330 of FIGS. 4 and 5). The shielding member 441 may be disposed between the display and at least one electronic component 421 and 423. According to an embodiment, the shielding member 441 may block and/or reduce the transmission of electromagnetic noise generated from at least one electronic component 421 and 423 to another electronic component disposed on the circuit board 410.

According to an embodiment, the shielding member 441 may cover the front surface of thermal interface material 430 (e.g., the surface facing in the +Z direction of FIG. 6).

According to an embodiment, the shielding member 441 may be attached to the shield can 450 through the adhesive member 445. The adhesive member 445 may include an adhesive material. The adhesive material may include, but is not limited to, a shielding double-sided tape. The adhesive member 445 may bond the shielding member 441 and the shield can 450. The adhesive member 445 may be compressed to adjust the component tolerance when assembling the board structure 400, but is not limited thereto.

According to an embodiment, the heat transfer member 443 (heat transfer) may be disposed between the shielding member 431 and the heat diffusion member 391. The heat transfer member 443 may contact the shielding member 431 and the heat diffusion member 391. The heat transfer member 443 may include a heat transfer material. The heat transfer material may include a thermal interface material of a material different from that of the thermal interface material 430 including the porous foam 431 and the liquid metal 433. For example, the heat transfer material may include, but is not limited to, thermal grease.

According to an embodiment, the electronic device 101 may include a heat diffusion member 391. For example, the heat diffusion member 391 may include a heat pipe, a vapor chamber, a graphite sheet, or a metal plate (e.g., a copper (Cu) plate). The heat diffusion member 391 may be defined and/or referred to as a heat spreader.

According to an embodiment, the heat dissipation member 391 may include a frame having thermal conductivity and a fluid disposed in the frame. As the fluid disposed in the frame of heat dissipation member 391 is vaporized by heat to move from one portion of heat dissipation member to another, heat generated from the electronic components 421 and 423 may be diffused or transferred through the heat dissipation member 391.

Referring to FIG. 6A, the heat diffusion member 391 may be disposed in a recess 311c recessed from the rear surface 311b of the first plate 311 toward the front surface 311a. For example, at least a portion of the first plate 311 may be disposed between the display (e.g., the display 320 of FIG. 4) and the heat diffusion member 391. According to an embodiment, the heat diffusion member 391 may be disposed in a hole (not illustrated) penetrating from the rear surface 311b of the first plate 311 toward the front surface 311a.

Referring to FIG. 6B, the heat dissipation member 3911 (e.g., the heat dissipation member 391 of FIG. 6A) may be disposed in a recess 3111c recessed from the front surface 311a to the rear surface 311b of the first plate 311. For example, the heat dissipation member 3911 may contact the display (e.g., the display 320 of FIG. 4), and at least a portion of heat dissipation member 3911 may be disposed between the display and the first plate 311.

Referring to FIGS. 6A and 6C, heat generated from the first electronic component 421 may be transferred to the heat diffusion member 443 through a heat dissipation path defined by the second electronic component 423, the thermal interface material 430, the shielding member 441, and the heat transfer member 443. The transferred heat may be dispersed on the heat diffusion member 443 or on the first plate 311.

According to an embodiment, the thermal interface material 430 may maintain a thin thickness as the porous foam 431 has compressibility. The thermal interface material 430 may have a high thermal conductivity due to the liquid metal 433 injected into the porous foam 431.

According to an embodiment, in the manufacturing process of thermal interface material 430, the liquid metal 433 may be injected into the porous foam 431 in a deoxidizing environment. Accordingly, the formation of an oxide layer between the liquid metal 433 and/or a plurality of liquid metal particles and the pores 431a of the porous foam 431 may be limited and/or reduced. Accordingly, the formation of an air gap between the liquid metal particles and the pores 431a may be limited and/or reduced, and thus the interfacial thermal resistance of the thermal interface material 430 may be enhanced, thereby enhancing thermal conductivity.

Referring to FIG. 6C, the stopper 460 may surround at least a portion of a side surface of the second electrical component 423 (e.g., the sides facing in the X-axis and Y-axis directions of FIG. 6C) and a side surface of thermal interface material 430 (e.g., the sides facing in the X-axis and Y-axis directions of FIG. 6C). For example, the stopper 460 may limit and/or reduce deformation of the thermal interface material 430. The stopper 460 may limit and/or prevent the liquid metal 433 of thermal interface material 430 from leaking to the front surface of the circuit board 421. According to an embodiment, the stopper 460 may include a non-conductive material. For example, the stopper 460 may include a polymer material such as rubber or styrene-ethylene-butylene-styrene (SEBS), but is not limited thereto.

Although not shown, the electronic device (e.g., the electronic device 101 of FIGS. 2 to 5) may include a battery (e.g., the battery 350 of FIGS. 4 and 5). The battery may be disposed on the rear surface 311b of the first plate 311. The heat dissipation member 391 may extend from a space between the first plate 311 and thermal interface material 430 to a space between the first plate 311 and the battery. A first end portion of the heat dissipation member 391 may overlap at least a portion of the thermal interface material 430, and a second end portion of the heat dissipation member 391 may overlap at least a portion of the battery. The heat dissipation member 391 may be configured to diffuse heat generated from at least one electronic component 421 and 423 through at least a portion of the thermal interface material 430, the first end portion of the heat dissipation member 391, and the second end portion of the heat dissipation member 391.

Referring to FIG. 7, the electronic device 101 and/or the board structure 400 may further include a heat transfer block 470.

According to an embodiment, the heat transfer block 470 may include a heat transfer material. For example, the heat transfer material may include copper (Cu), but is not limited thereto. The heat transfer characteristics of the heat transfer block 470 may be different from the heat transfer characteristics of the thermal interface material 430.

According to an embodiment, the heat transfer block 470 may be disposed between the thermal interface material 430 and the first electronic component 421. The heat transfer block 470 may contact the thermal interface material 430. For example, at least one surface of the heat transfer block 470 (e.g., the surface facing in the +Z direction of FIG. 7) may contact the thermal interface material 430. The heat transfer block 470 may be attached to the front surface of the first electronic component 421 through the adhesive layer 472 of the thermal interface material 430. For example, the adhesive layer 472 may include a thermally conductive adhesive and may be configured to transfer heat from the first electronic component 470 to the heat transfer block 470.

According to an embodiment, the heat transfer block 470 may be spaced apart from the second electronic component 423. For example, the air gap may be formed between the heat transfer block 470 and the second electronic component 423. Although not shown, the heat transfer block 470 may be disposed to contact the second electronic component 423.

According to an embodiment, the heat transfer block 470 may be disposed between the thermal interface material 430 and the first electronic component 421. The heat transfer block 470 may be configured not to overlap the second electronic component 423 when viewed in a direction (e.g., the Z-axis direction of FIG. 6A) substantially perpendicular to the display. For example, the heat transfer block 470 may not overlap the second electronic component 423 when viewed from the display toward the circuit board 410.

According to an embodiment, heat generated from the first electronic component 421 may be transferred to the heat diffusion member 443 through the first heat dissipation path RI defined by the second electronic component 423, the thermal interface material 430, the shielding member 441, and the heat transfer member 443. Heat transferred through the first heat dissipation path R1 may be dispersed on the heat diffusion member 443 or on the first plate 311.

According to an embodiment, heat generated from the first electronic component 421 may be transferred to the heat diffusion member 443 through a second heat dissipation path R2 defined by the adhesive layer 472, the heat transfer block 470, the thermal interface material 430, the shielding member 441, and the heat transfer member 443. Heat transferred through the second heat dissipation path R2 may be dispersed on the heat diffusion member 443 or on the first plate 311.

According to an embodiment, the thermal conductivity of the heat transfer block 470 may be larger than the thermal conductivity of the second electronic component 423. Accordingly, in the same time range, the amount of heat transferred to the heat diffusion member 443 through the second heat dissipation path R2 may be larger than the amount of heat transferred to the heat diffusion member 443 through the first heat dissipation path R1.

According to an embodiment, as thermal conductivity through the second heat dissipation path R2 is relatively excellent, the first electronic component 421 (e.g., the processor 120 of FIG. 1) may be designed so that elements having a relatively high heat generation amount are positioned adjacent to or corresponding to the heat transfer block 470, but the disclosure is not limited thereto. Although not shown, the second electronic component 423 may be positioned or aligned in the center portion or center of the front surface of the first electronic component 421, and the heat transfer block 470 may be disposed to surround the second electronic component 423. For example, when viewed in the thickness direction of the board structure 400 (e.g., the Z-axis direction of FIG. 7), the heat transfer block 470 may be overall formed in a loop shape, and the second electronic component 423 may be disposed inside the loop defined by the heat transfer block 470.

According to an embodiment, the thermal interface material 430 may be disposed to overlap at least a partial area of the front surface of the first electronic component 421. At least a portion of the thermal interface material 430 may form a porous foam (e.g., the porous foam 431 of FIG. 6A) including one or more pores (e.g., the pores 431a of FIG. 6A) substantially filled with a liquid metal (e.g., the liquid metal 433 of FIG. 6A).

According to an embodiment, the heat transfer block 470 may be disposed between the at least one portion of the thermal interface material 430 and the first area of the front surface of the first electronic component 421.

According to an embodiment, the second electronic component 423 may be disposed between another portion of the thermal interface material 430 and the second area of the front surface of the first electronic component 421. The second area of the front surface of the first electronic component 421 may not overlap the first area of the front surface of the first electronic component 421.

According to an embodiment, the first electronic component 421 may form a processor (e.g., the processor 120 of FIG. 1), and the second electronic component 423 may form memory (e.g., the memory 130 of FIG. 1).

Referring to FIG. 8A, the second electronic component 423 (e.g., the memory 130 of FIG. 1) may include at least one groove 423b recessed in the surface 423a of the second electronic component 423 in contact with the thermal interface material 430. As the surface 423a of the second electronic component 423 is roughly formed, the coupling area between the thermal interface material 430 and the surface 423a of the second electronic component 423 may increase.

Referring to FIG. 8B, the surface of the heat transfer block 470 contacting the thermal interface material 430 may be flat, but is not limited thereto.

FIG. 9 is a cross-sectional view illustrating a board structure according to an embodiment.

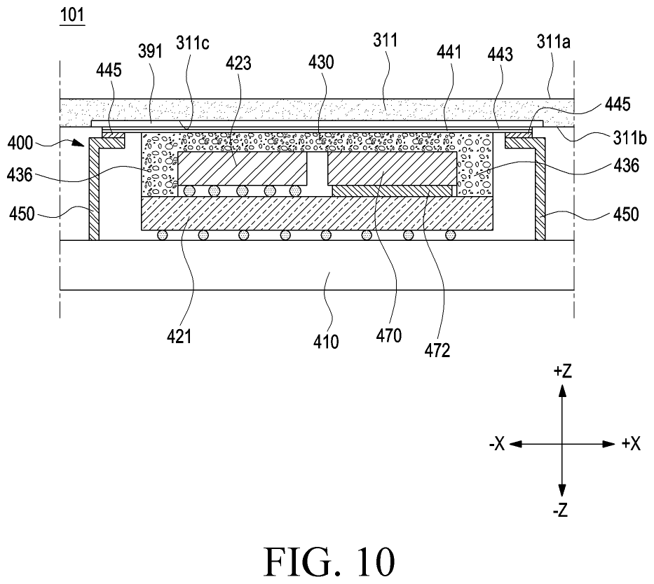

The embodiment of FIG. 9 may be combined with the embodiments of FIGS. 1, 2, 3, 4, 5, 6A, 6B, 6C, 7, 8A and 8B (which may be referred to as FIGS. 1 to 8B, or the embodiments of FIGS. 10, 11, 12 and 13 (which may be referred to as FIGS. 10 to 13).

The configurations of the embodiments of FIG. 9 may be identical in whole or part to the configurations of the embodiments of FIGS. 1 to 8B, or the configurations of the embodiments of FIGS. 10 to 13.

Referring to FIG. 9, a board structure 400 (e.g., the board structure 400 of FIGS. 6 and 7) may include a thermal interface material 430 (e.g., the thermal interface material 430 of FIGS. 6 to 8B).

According to an embodiment, a first portion 430a of the thermal interface material 430 may be stacked on the second electronic component 423. A second portion 430b of the thermal interface material 430 may extend from the first portion 430a. The second portion 430b of the thermal interface material 430 may be stacked on the heat transfer block 4701 (e.g., the heat transfer block 470 of FIG. 7).

According to an embodiment, depending on the thickness of the adhesive layer 472 and the thickness of the heat transfer block 4701, the height h2 between the front surface of the heat transfer block 4701 (e.g., the surface facing in the +Z direction of FIG. 9) and the front surface of the first electronic component 421 (e.g., the surface facing in the +Z direction of FIG. 9) may be larger than the height h1 between the front surface of the second electronic component 423 (e.g., the surface facing in the +Z direction of FIG. 9) and the front surface of the first electronic component 421.

According to an embodiment, the thickness t2 (e.g., the thickness in the Z-axis direction of FIG. 9) of the second portion 430b stacked on the heat transfer block 4701 may be different from the thickness t1 (e.g., the thickness in the Z-axis direction of FIG. 9) of the first portion 430a stacked on the second electronic component 423. For example, the thickness t2 of the second portion 430b may be smaller than the thickness t1 of the first portion 430a. According to an embodiment, a third portion 430c of the thermal interface material 430 may be disposed between the first portion 430a and the second portion 430b to be connected to the first portion 430a and the second portion 430b. The third portion 430c may be positioned corresponding to the air gap formed between the second electronic component 423 and the heat transfer block 4701. The thickness of the third portion 430c may be substantially the same as the thickness t1 of the first portion 430a, but is not limited thereto. Although not shown, e.g., the thickness of the third portion 430c may be formed to be equal to the thickness of the second portion 430b. The third portion 430c may be interpreted as a portion of the first portion 430a, but is not limited thereto. For example, the third portion 430c may be interpreted as a portion of the second portion 430b.

According to an embodiment, as the porosity and/or pore density of the thermal interface material 430 is set differently for each portion, the thermal interface material 430 may appropriately adjust its thickness according to the thickness or height of the corresponding component. Accordingly, the overall thickness or the overall height of the board structure 400 may be uniformly designed or manufactured. For example, the porosity and/or pore density of the second portion 430b corresponding to a component with a relatively large thickness or height (e.g., the heat transfer block 4701) may be set to be relatively high, and the porosity and/or pore density of the first portion 430a corresponding to a component with a relatively small thickness or height (e.g., the second electronic component 423) may be set to be relatively low. In this case, the compression rate of the second portion 430b corresponding to a component having a large height is set to be high, so that the second portion 430b may be compressed relatively much during the assembly process, and the compression rate of the first portion 430a corresponding to a component having a small height is set to be low, so that the first portion 430a may be compressed relatively little during the assembly process. Accordingly, the overall thickness or overall height of the board structure 400 may be uniformly designed, and excessive pressure applied to any one component may be limited and/or reduced.

According to an embodiment, the size of the liquid metal particles 433a injected into the first portion 430a may be smaller than the size of the liquid metal particles 433b injected into the second portion 430b, but is not limited thereto.

Although not shown, depending on the size of the second electronic component 423 and the heat transfer block 4701, the thickness of the second portion 430b may be larger than the thickness of the first portion 430a.

According to an embodiment, the thermal interface material 430 may be disposed to overlap at least a partial area of the front surface of the first electronic component 421.

According to an embodiment, the heat transfer block 470 may be disposed between at least one portion 430b (e.g., the second portion 430b) of the thermal interface material 430 and the first area of the front surface of the first electronic component 421.

According to an embodiment, the second electronic component 423 may be disposed between another portion 430a (e.g., the first portion 430a) of the thermal interface material 430 and the second area of the front surface of the first electronic component 421. The second area of the front surface of the first electronic component 421 may not overlap the first area of the front surface of the first electronic component 421.

According to an embodiment, the first electronic component 421 may form a processor (e.g., the processor 120 of FIG. 1), and the second electronic component 423 may form memory (e.g., the memory 130 of FIG. 1).

According to an embodiment, the at least one portion 430b of the thermal interface material 430 and the other portion 430a of the thermal interface material 430 may have different thicknesses, porosities, or pore densities.

According to an embodiment, the pores formed in the other portion 430a of the thermal interface material 430 may be substantially filled with non-conductive materials or air gaps.

According to an embodiment, the thermal interface material 430 may form a portion of a chip package together with the first electronic component 421 including a processor and the second electronic component 423 including memory.

FIG. 10 is a cross-sectional view illustrating a circuit board and an electronic device according to an embodiment.

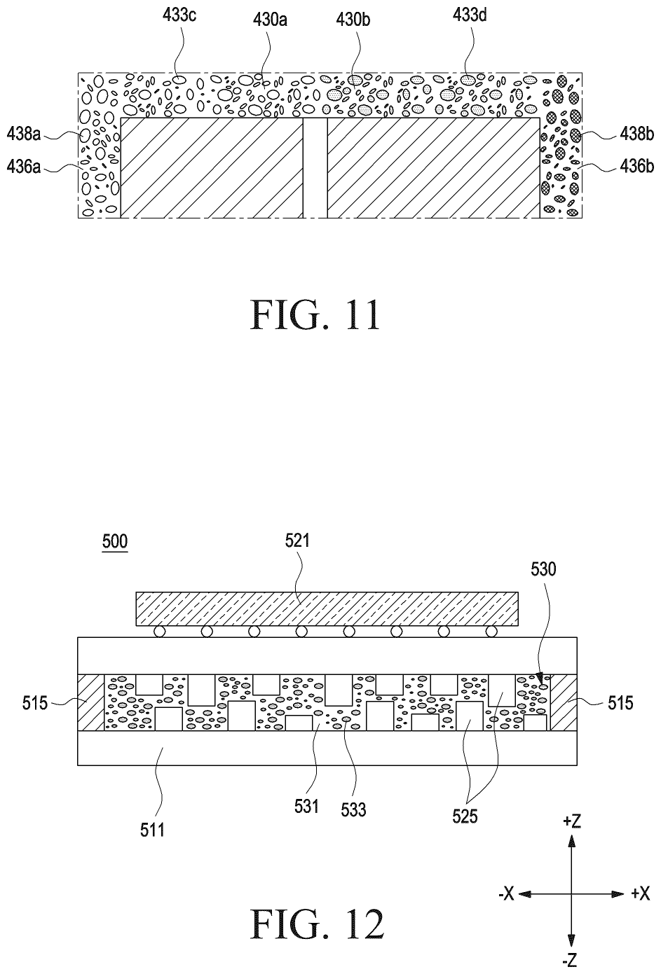

FIG. 11 is a cross-sectional view illustrating a second electronic component, a heat transfer block, and a thermal interface material according to an embodiment.

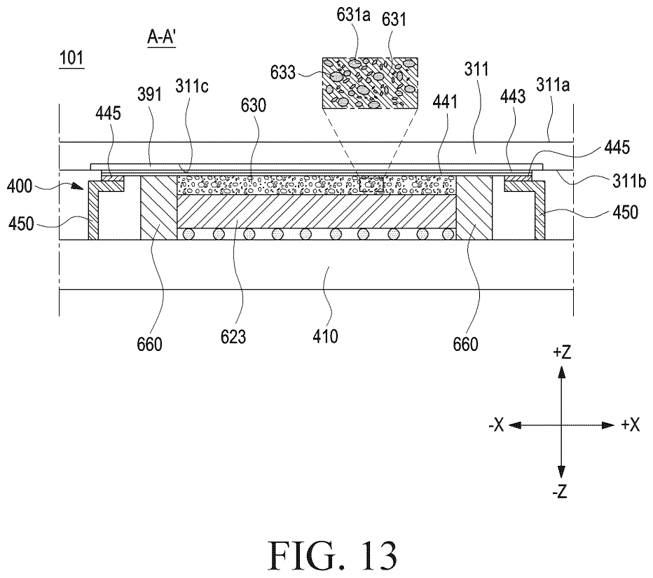

The embodiments of FIGS. 10 and 11 may be combined with the embodiments of FIGS. 1, 2, 3, 4, 5, 6A, 6B, 6C, 7, 8A, 8B and 9 (which may be referred to as FIGS. 1 to 9), or the embodiment of FIG. 13.

The configurations of the embodiments of FIGS. 10 and 11 may be identical in whole or part to the configurations of the embodiments of FIGS. 1 to 9, or the configurations of the embodiments of FIGS. 12 and 13.

The configurations of the embodiments of FIGS. 10 and 11 may be identical in whole or part to the configurations of the embodiments of FIGS. 1 to 9, or the configurations of the embodiments of FIGS. 12 and 13.

Referring to FIGS. 10 and 11, the electronic device 101 (e.g., the electronic device 101 of FIGS. 2 to 7) may include a board structure 400 (e.g., the board structure 400 of FIGS. 6 and 7).

According to an embodiment, the thermal interface material 430 (e.g., the thermal interface material 430 of FIGS. 6 and 7) may cover at least a portion of the outer surface of the second electronic component 423 (e.g., the second electronic component 423 of FIG. 7) and at least a portion of the outer surface of the heat transfer block 470 (e.g., the heat transfer block 470 of FIG. 7).

According to an embodiment, the thermal interface material 430 may contact and/or be connected to the front surface of the second electronic component 423 (e.g., the surface facing in the +Z direction of FIG. 10) and at least a portion of the side surface of the second electronic component 423 (e.g., the side facing in the −X direction of FIG. 10). When the thermal interface material 430 contacts and/or is connected to at least a portion of the side surface of the second electronic component 423, it may be defined and/or interpreted as the thermal interface material 430 contacting and/or being connected to at least two or more of the plurality of side surfaces of the second electronic component 423.

According to an embodiment, the thermal interface material 430 may contact and/or be connected to the front surface of the heat transfer block 470 (e.g., the surface facing in the +Z direction of FIG. 10) and at least a portion of the side surface of the heat transfer block 470 (e.g., the surface facing in the +X direction of FIG. 10).

According to an embodiment, the thermal interface material 430 may include a stopper 436 (e.g., the stopper 460 of FIGS. 6 and 7). The stopper 436 may include a third portion (e.g., the third portion 436a of FIG. 11) and a fourth portion (e.g., the fourth portion 436b of FIG. 11).

Referring to FIG. 11, the thermal interface material 430 may include a first portion 430a, a second portion 430b, a third portion 436a, and a fourth portion 436b.

According to an embodiment, the first portion 430a may be stacked on the front surface of the second electronic component 423.

According to an embodiment, an air gap 433c may be formed in the pores corresponding to the first portion 430a. For example, the liquid metal may not be injected into the pores of the first portion 430a. According to an embodiment, non-conductive particles or liquid metal particles may be injected into the pores of the first portion 430a.

According to an embodiment, the third portion 436a may be stacked on the side surface of the second electronic component 423. The third portion 436a may function as a stopper (e.g., the stopper 460 of FIG. 7) that limits and/or reduces deformation of the first portion 430a, but is not limited thereto.

According to an embodiment, an air gap 438a may be formed in the pores corresponding to the third portion 436a. For example, a liquid metal may not be injected into the pores of the third portion 436a. According to an embodiment, a smaller amount of liquid metals may be injected into the pores corresponding to the third portion 436a than the liquid metals injected into the pores of the first portion 430a and/or the second portion 430b. For example, the liquid metals may be injected into at least some of the pores of the third portion 436a, and an air gap may be formed in the rest of the pores of the third portion 436a. According to an embodiment, the liquid metals injected into the pores of the first portion 430a and/or the second portion 430b may move to the pores of the third portion 436a when the thermal interface material 430 is pressed during the assembly process.

According to an embodiment, since the second electronic component 423 does not have a large amount of heat generated, the liquid metal may not be injected into the first portion 430a and the third portion 436a corresponding to the second electronic component 423. Accordingly, the thermal conductivity of the first portion 430a and the third portion 436a may be smaller than the thermal conductivity of the second portion 430b.

According to an embodiment, the second portion 430b may be stacked on the front surface of the heat transfer block 470.

According to an embodiment, the liquid metal particles 433d may be injected into the pores corresponding to the second portion 430b.

According to an embodiment, the fourth portion 436b may be stacked on the side surface of the heat transfer block 470. The fourth portion 436b may function as a stopper (e.g., the stopper 460 of FIG. 7) that limits and/or reduces deformation of the second portion 430b, but is not limited thereto.

According to an embodiment, non-conductive particles 438b may be injected into the pores corresponding to the fourth portion 436b. The non-conductive particles 438b may be a polymer-based material including silicone oil or polydimethylsiloxane (PDMS), but are not limited thereto.

According to an embodiment, as the non-conductive particles 438b are injected into the pores of the fourth portion 436b, even if the non-conductive particles of the fourth portion 436b leak to the front surface of the circuit board (e.g., the circuit board 410 of FIG. 10), the electrical connection between the elements on the front surface of the circuit board 410 may be limited and/or prevented.

According to an embodiment, an air gap may be formed in the pores corresponding to the fourth portion 436b. According to an embodiment, a smaller amount of liquid metals may be injected into the pores corresponding to the fourth portion 436b than the liquid metals injected into the pores of the first portion 430a and/or the second portion 430b. For example, the liquid metals may be injected into at least some of the pores of the fourth portion 436b, and an air gap may be formed in the rest of the pores of the fourth portion 436b. According to an embodiment, the liquid metals injected into the pores of the first portion 430a and/or the second portion 430b may move to the pores of the fourth portion 436b when the thermal interface material 430 is pressed during the assembly process.

According to an embodiment, a liquid metal may be injected into the pores of the first portion 430a and the second portion 430b, and an air gap may be formed in the pores of the third portion 436a and the fourth portion 436b.

According to an embodiment, a liquid metal may be injected into the pores of the first portion 430a and the second portion 430b, and non-conductive particles (e.g., the silicone oil or polydimethylsiloxane (PDMS)) may be injected into the pores of the third portion 436a and the fourth portion 436b.

According to an embodiment, the third portion 436a may be defined and/or referred to as a first edge portion 436a extending from the first portion 430a of the thermal interface material 430 and surrounding at least a portion of the side edge of the second electronic component 423 including the memory. The fourth portion 436b may be defined and/or referred to as a second edge portion 436b extending from the second portion 430b of the thermal interface material 430 and surrounding at least a portion of the side edge of the heat transfer block 470.

According to an embodiment, one end of the third portion 436a (e.g., the first edge portion) and one end of the fourth portion 436b (e.g., the second edge portion) may contact the first edge area and the second edge area, respectively, of the first electronic component 421 including the processor.

According to an embodiment, the pores formed in the third portion 436a (e.g., the first edge portion) or the pores formed in the fourth portion 436b (e.g., the second edge portion) may be substantially filled with a non-conductive material (e.g., the non-conductive particles), or air (e.g., an air gap).

FIG. 12 is a cross-sectional view illustrating a board structure according to an embodiment.

The embodiment of FIG. 12 may be combined with the embodiments of FIGS. 1, 2, 3, 4, 5, 6A, 6B, 6C, 7, 8A, 8B, 9, 10 and 11 (which may be referred to as FIGS. 1 to 11) or the embodiment of FIG. 13.

The configurations of the embodiment of FIG. 12 may be partially or entirely combined with the configurations of the embodiments of FIGS. 1 to 11, or the configurations of the embodiments of FIG. 13.

Referring to FIG. 12, a board structure 500 (e.g., the board structure 500 of FIGS. 6 and 7) may include an interposer circuit board.

According to an embodiment, the board structure 500 may include a first substrate 511 and a second substrate 513 disposed above the first substrate 511 (e.g., the +Z direction). The board structure 500 may include a sidewall 515 connected to the first substrate 511 and the second substrate 513 and including a conductive via.

According to an embodiment, the board structure 500 may include a plurality of elements 525 disposed on the inner surface of the first substrate 511 (e.g., the surface facing the second substrate 513) or the inner surface of the second substrate 513 (e.g., the surface facing the first substrate 511). The plurality of elements 525 may be defined and/or referred to as at least one electronic component.

According to an embodiment, the board structure 500 may include a first electronic component 521 (e.g., the first electronic component 421 of FIGS. 6 and 7) disposed on the outer surface of the second substrate 513.

According to an embodiment, the board structure 500 may include a thermal interface material 530 (e.g., the thermal interface material 430 of FIGS. 6 and 7) received in the inner space of the board structure 500 defined by the first substrate 511, the second substrate 513, and the sidewall 515.

According to an embodiment, the thermal interface material 530 may include a porous foam 531 (e.g., the porous foam 431 of FIGS. 6 and 7) and a phase change material 533 (PCM) injected into the porous foam 531. The phase change material 533 may be defined and/or referred to as a filler material filled in the porous foam 531.

According to an embodiment, the phase change material 533 may include an organic phase change material (organic PCM). For example, the phase change material 533 may include a non-conductive material. For example, the phase change material 533 may include, but is not limited to, paraffin wax, polydimethylsiloxane (PDMS), or silicone oil.

According to an embodiment, as the phase change material 533 includes a non-conductive material, electrical connection of a plurality of elements 525 disposed in the inner space may be limited and/or reduced.

FIG. 13 is a cross-sectional view illustrating a board structure according to an embodiment.

The embodiment of FIG. 13 may be combined with the embodiments of FIGS. 1, 2, 3, 4, 5 6A, 6B, 6C, 7, 8A, 8B, 9, 10, 11 and 12 (which may be referred to as FIGS. 1 to 12).

The configurations of the embodiment of FIG. 13 may be identical in whole or part to the configurations of the configurations of the embodiments of FIGS. 1 to 12.

The configurations of the board structure 400, the circuit board 410, the shield can 450, the adhesive member 445, the shielding member 441, the heat transfer member 443, the heat diffusion member 391, or the first plate 311 of FIG. 13 may be identical in whole or part to the configurations of the board structure 400, the circuit board 410, the shield can 450, the adhesive member 441, the heat transfer member 443, the heat diffusion member 391, or the first plate 311 of FIG. 6A, 6B, 6C and FIG. 7.

Referring to FIG. 13, the board structure 400 may include an electronic component 623 (e.g., the at least one electronic component 421 and 423 of FIG. 6A). The electronic component 623 may include a chip package. For example, the electronic component 623 in the form of a chip package may include a plurality of electronic elements disposed inside the electronic component 623. The plurality of electronic elements may include an integrated circuit. For example, the electronic component 623 may be defined as forming a chip package. According to an embodiment, it may be defined and/or interpreted as the electronic component 623 and the thermal interface material 630 together forming at least a portion of the chip package.

According to an embodiment, the electronic component 623 may include a processor (e.g., the processor 120 of FIG. 1). The electronic component 623 may include a processor (e.g., the processor 120 of FIG. 1) and memory (e.g., the memory 130 of FIG. 1).

According to an embodiment, the thermal interface material 630 (e.g., the thermal interface material 430 of FIG. 6A) may be disposed to overlap at least a partial area of one surface of the electronic component 623 (e.g., the surface facing in the +Z direction of FIG. 13).

According to an embodiment, the thermal interface material 630 may be disposed between the electronic component 623 and the first plate 311.

According to an embodiment, a portion of the thermal interface material 630 may form a porous foam 631 (e.g., the porous foam 431 of FIG. 6A) including one or more pores 631a (e.g., the pores 431a of FIG. 6A) substantially filled with a liquid metal 633 (e.g., the liquid metal 433 of FIG. 6A).

According to an embodiment, the liquid metal 633 may be configured to remain in a liquid state when the electronic component 623 generates heat above a set temperature value.

According to an embodiment, the stopper 660 (e.g., the stopper 460 of FIG. 6A) may be disposed in the first edge area (e.g., the edge or edge area toward the +X direction of FIG. 13) and the second edge area (e.g., the edge or edge area toward the −X direction of FIG. 13) of the electronic component 623 including the processor. The stopper 660 may substantially surround the first side edge (e.g., the side surface or edge facing in the +X direction of FIG. 13) and the second side edge (e.g., the side surface or edge facing in the −X direction of FIG. 13) facing away from each other.

An electronic device may include various heat dissipation members for dissipating heat generated from a circuit board and an electronic component disposed thereon. For example, the heat dissipation member may include a thermal interface material (TIM) that contacts at least a portion of the electronic component to dissipate and/or disperse heat generated from the electronic component.

Various types of thermal interface materials are disclosed to enhance the thermal conductivity of the thermal interface material, but it is difficult to design a thermal interface material having sufficient thermal conductivity in a narrow inner space of an electronic device.

According to an embodiment of the disclosure, there may be provided an electronic device with enhanced heat dissipation efficiency through a thermal interface material including a liquid metal.

However, the disclosure is not limited to the foregoing objects but rather may be expanded in various manners without departing from the spirit and scope of the disclosure.

According to an embodiment of the disclosure, there may be provided a heat dissipation structure including a thermal interface material that secures sufficient heat dissipation efficiency in a limited inner space through a thermal interface material with enhanced compression ratio and thermal conductivity and an electronic device including the same.

Effects obtainable from the disclosure are not limited to the above-mentioned effects, and other effects not mentioned may be apparent to one of ordinary skill in the art from the description.

According to an example embodiment of the disclosure, an electronic device 101 may comprise a housing 301 including a plate 311.

According to an example embodiment, the electronic device 101 may comprise a display 330 disposed on a front surface 311a of the plate 311.

According to an example embodiment, the electronic device 101 may comprise a circuit board 410 disposed inside the housing 310 and including an electronic component 421, 423.

According to an example embodiment, the electronic device 101 may comprise a thermal interface material 430 configured to transfer heat generated from the electronic component 421, 423 to another component included in the electronic device 101.

According to an example embodiment, the thermal interface material 430 may include a porous foam 431 configured to cover at least a portion of an outer surface of the electronic component, and at least partially disposed between a rear surface 311b of the plate 311 and the circuit board 410, and having compressibility.

According to an example embodiment, the thermal interface material 430 may include a liquid metal 433.

According to an example embodiment, the liquid metal 433 may include a plurality of liquid metal particles received in the plurality of pores 431a of the porous foam 431.

According to an example embodiment, a thermal conductivity of the thermal interface material 430 may be 17 W/(m×K) to 33 W/(m×K).

According to an example embodiment, the liquid metal 433 may include a eutectic alloy including gallium, indium, tin, or two or more thereof.

According to an example embodiment, the electronic component 421, 423 may include a first electronic component 421 disposed on a front surface of the circuit board 410 and having a first area, and a second electronic component 423 disposed on a front surface of the first electronic component 421 and having a second area smaller than the first area.

According to an example embodiment, the thermal interface material 430 may be configured to substantially overlap the first electronic component 421 when viewed in a direction perpendicular to the display 330.

According to an example embodiment, the thermal interface material 430 may be configured to cover at least a portion of an outer surface of the second electronic component 423.

According to an example embodiment, the first electronic component 421 may include a processor, and the second electronic component 423 may include memory.

According to an example embodiment, the electronic device 101 may further comprise a heat transfer block 470 disposed between the thermal interface material 430 and the first electronic component 421 and configured to not overlap the second electronic component 423 when viewed in the direction substantially perpendicular to the display 330.

According to an example embodiment, a thermal conductivity of the heat transfer block 470 may be greater than a thermal conductivity of the second electronic component 423.

According to an example embodiment, the thermal interface material 430 may include a first portion 430a disposed on a front surface of the second electronic component 423 and a second portion 430b disposed on a front surface of the heat transfer block 430b.

According to an example embodiment, a thickness of the second portion 430b may be different from a thickness of the first portion 430a.

According to an example embodiment, pores formed in the first portion 430a may be filled with a non-conductive material or air.

According to an example embodiment, pores formed in the second portion 430b may be filled with the liquid metal 433d.

According to an example embodiment, the thermal interface material 430 may further include a third portion 436a extending from the first portion 430a and configured to cover at least a portion of a side surface of the second electronic component 423, and a fourth portion 436b extending from the second portion 430b and configured to cover at least a portion of a side surface of the heat transfer block 470.

According to an example embodiment, pores formed in the third portion 436a may be substantially filled with air.

According to an example embodiment, pores formed in the fourth portion 436b may be substantially filled with a non-conductive material.

According to an example embodiment, the housing 301 may further include a recess 311c recessed from the rear surface 311b of the plate 311 toward the front surface 311a of the plate 311.

According to an example embodiment, the electronic device 101 may further comprise a heat diffusion member 391 disposed in the recess 311c.

According to an example embodiment, the porous foam 431 may include at least one of copper (Cu), silver (Ag), gold (Au), nickel (Ni), or hexagonal boron nitride (h-BN).

According to an example embodiment, a porosity of the porous foam 431 may be 75% to 99%.

According to an example embodiment, a pore density of the porous foam 431 may be 20 ppi to 150 ppi.

According to an example embodiment, the compression ratio of the porous foam 431 may be 23% to 42% at 1 kgf/cm².

According to an example embodiment of the disclosure, an electronic device 101 may comprise a housing 301 including a plate 311.

According to an example embodiment, the electronic device 101 may comprise a display 330 disposed on a front surface 311a of the plate 311.

According to an example embodiment, the electronic device 101 may comprise a circuit board 410 disposed inside the housing 310 and including at least one electronic component 421, 423.

According to an example embodiment, the electronic device 101 may comprise a thermal interface material 430 configured to dissipate heat generated from the at least one electronic component 421, 423.

According to an example embodiment, the thermal interface material 430 may include a porous foam 431, 531 configured to cover at least a portion of an outer surface of the electronic component, and at least partially disposed between a rear surface 311b of the plate 311 and the circuit board 410, and having compressibility.

According to an example embodiment, the thermal interface material 430 may include a filler material 433, 533 filling the porous foam 431, 531.

According to an example embodiment, an air gap 433c may be formed in at least a portion of the porous foam 431, 531.

According to an example embodiment, the filler material 433 may include a liquid metal.

According to an example embodiment, the liquid metal may be injected into the porous foam 431 in a deoxidizing environment.

According to an example embodiment, the filler material 533 may include an organic phase change material.

According to an example embodiment, the electronic device 101 may further comprise a shielding member 441 disposed between the thermal interface material 430 and a rear surface 311b of the plate 311.

According to an example embodiment, the electronic device 101 may further comprise a heat transfer member 443 disposed between the shielding member 441 and the rear surface 311b of the plate 311 and including a heat transfer material.

According to an example embodiment of the disclosure, an electronic device 101 may comprise a housing 301, an electronic component 421 received in the housing 301, and a thermal interface material 430 (or a thermal interface member) disposed to overlap at least a partial area of one surface of the electronic component 421.

According to an example embodiment, at least a portion of the thermal interface material 430 may comprise a porous foam 431 including one or more pores 431a substantially filled with a liquid metal 433.

According to an example embodiment, the liquid metal 433 may be configured to remain in a liquid state when heated at a designated temperature value or more in the electronic component 421.

According to an example embodiment, the electronic device 101 may further comprise a heat transfer block 470 disposed between the at least a portion of the thermal interface material 430 and a first area of the one surface of the electronic component 421 and having a thermal conductivity characteristic different from the thermal interface material 430.

According to an example embodiment, the heat transfer block 470 may be configured to transfer heat generated from the electronic component 421 to the at least a portion of the thermal interface material 430.

According to an example embodiment, the electronic device 101 may further comprise another electronic component 423 disposed between another portion of the thermal interface material 430 and a second area of the one surface of the electronic component not overlapping the first area.

According to an example embodiment, the electronic component 421 may include a processor, and the other electronic component 423 may include a memory.

According to an example embodiment, the at least a portion of the thermal interface material 430 and the other portion may have different thicknesses, porosities, or pore densities.

According to an example embodiment, pores formed in the other portion of the thermal interface material 430 may be substantially filled with a non-conductive material or air.

According to an example embodiment, the electronic device 101 may further comprise a stopper 660 substantially surrounding a first side edge and a second side edge facing each other, of the thermal interface material and disposed in a first edge area and a second edge area of the one surface of the processor.

According to an example embodiment, the thermal interface material 430 may include a first edge portion 436a extending from the other portion and surrounding at least a portion of a side edge of the other electronic component 423 and a second edge portion 436b extending from the at least a portion and surrounding at least a portion of a side edge of the heat transfer block 470.

According to an example embodiment, one end of the first edge portion 436a and one end of the second edge portion 436b may contact the first edge area and the second edge area, respectively, of the one surface of the processor.

According to an example embodiment, pores formed in the first edge portion 436a or pores formed in the second edge portion 436b may be substantially filled with a non-conductive material or air.

According to an example embodiment, the electronic device 101 may further comprise a battery 350, a display 330, a plate 311 receiving the display 330, and a heat dissipation member 391 extending from between the plate 311 and the thermal interface material 430 to between the plate 311 and the battery 350.

According to an example embodiment, a first end portion and a second end portion of the heat dissipation member 391 may be configured to be positioned to overlap the portion of the thermal interface material 430 and a portion of the battery 350, respectively, to diffuse heat generated from the electronic component 421, 423 to the portion of the thermal interface material 430, the first end portion of the heat dissipation member 391, and the second end portion of the heat dissipation member 391.

While the disclosure has been illustrated and described with reference to various example embodiments thereof, it will be apparent to those skilled in the art that various changes in form and detail may be made thereto without departing from the spirit and scope of the disclosure including the appended claims and their equivalents. It will also be understood that any of the embodiment(s) described herein may be used in conjunction with any other embodiment(s) described herein.

What is claimed is:

1. An electronic device comprising:
a housing including a plate;
a display disposed on a front surface of the plate;
a circuit board disposed inside the housing and including an electronic component; and
a thermal interface material configured to transfer heat generated from the electronic component to another component included in the electronic device,
wherein the thermal interface material includes:
a porous foam configured to cover at least a portion of an outer surface of the electronic component, and at least partially disposed between a rear surface of the plate and the circuit board; and
a liquid metal included in the porous foam.

2. The electronic device of claim 1,
wherein a thermal conductivity of the thermal interface material is in a range of 17 W/(m×K) to 33 W/(m×K).

3. The electronic device of claim 1,
wherein the liquid metal includes a eutectic alloy including gallium, indium, tin, or two or more thereof.

4. The electronic device of claim 1,
wherein the electronic component includes a first electronic component disposed on a front surface of the circuit board and having a first area, and a second electronic component disposed on a front surface of the first electronic component and having a second area smaller than the first area, and
wherein the thermal interface material is configured to substantially overlap the first electronic component when viewed in a direction perpendicular to the display.

5. The electronic device of claim 4,
wherein the first electronic component includes a processor, and
wherein the second electronic component includes memory.

6. The electronic device of claim 5, further comprising a heat transfer block disposed between the thermal interface material and the first electronic component and configured to not overlap the second electronic component when viewed in the direction perpendicular to the display.

7. The electronic device of claim 6,
wherein a thermal conductivity of the heat transfer block is greater than a thermal conductivity of the second electronic component.

8. The electronic device of claim 5,
wherein the thermal interface material includes a first portion disposed on a front surface of the second electronic component and a second portion disposed on a front surface of the heat transfer block, and
wherein a thickness of the second portion is different from a thickness of the first portion.

9. The electronic device of claim 8,
wherein pores formed in the first portion are substantially filled with a non-conductive material or air, and
wherein pores formed in the second portion are substantially filled with the liquid metal.

10. The electronic device of claim 8,
wherein the thermal interface material further includes a third portion extending from the first portion and configured to cover at least a portion of a side surface of the second electronic component, and a fourth portion extending from the second portion and configured to cover at least a portion of a side surface of the heat transfer block.

11. The electronic device of claim 10,
wherein pores formed in the third portion are substantially filled with air, and
wherein pores formed in the fourth portion are substantially filled with a non-conductive material.

12. The electronic device of claim 1,
wherein the housing further includes a recess recessed from the rear surface of the plate toward the front surface of the plate, and
wherein the electronic device further comprises a heat diffusion member comprising a heat diffusing material disposed in the recess.

13. The electronic device of claim 1,
wherein the porous foam includes at least one of copper (Cu), silver (Ag), gold (Au), nickel (Ni), or hexagonal boron nitride (h-BN).

14. The electronic device of claim 1,
wherein a porosity of the porous foam is in a range of 75% to 99%, and
wherein a pore density of the porous foam is in a range of 20 ppi to 150 ppi.

15. An electronic device comprising:
a housing;
an electronic component received in the housing; and
a thermal interface material disposed to overlap at least a partial area of one surface of the electronic component, wherein at least a portion of the thermal interface material includes a porous foam including one or more pores substantially filled with a liquid metal.

16. The electronic device of claim 15, wherein the liquid metal is configured to remain in a liquid state when heated at a designated temperature value or more in the electronic component.

17. The electronic device of claim 15, further comprising a heat transfer block disposed between the at least a portion of the thermal interface material and a first area of the one surface of the electronic component and having a thermal conductivity characteristic different from the thermal interface material, wherein the heat transfer block is configured to transfer heat generated from the electronic component to the at least a portion of the thermal interface material.

18. The electronic device of claim 17, further comprising another electronic component disposed between another portion of the thermal interface material and a second area of the one surface of the electronic component not overlapping the first area.

19. The electronic device of claim 18, wherein the electronic component includes a processor, and wherein the other electronic component includes memory.

20. The electronic device of claim 18, wherein the at least a portion of the thermal interface material and the other portion have different thicknesses, porosities, or pore densities.
